(19) United States
(12) Patent Application Publication
(10) Pub. No.: US 2026/0047247 A1
(43) Pub. Date: Feb. 12, 2026

(54) LIGHT EMITTING DEVICE AND DISPLAY DEVICE

(71) Applicant: NICHIA CORPORATION, Anan-shi (JP)

(72) Inventors: Kenta MITSUYAMA, Anan-shi (JP); Yoshio ICHIHARA, Anan-shi (JP); Kazuaki SAKAI, Tokushima-shi (JP)

(73) Assignee: NICHIA CORPORATION, Anan-shi (JP)

(21) Appl. No.: 19/100,356

(22) PCT Filed: Mar. 27, 2023
(86) PCT No.: PCT/JP2023/012122

§ 371 Date: Jan. 31, 2025

(30) Foreign Application Priority Data
Aug. 3, 2022 (JP) 2022-124389
Dec. 16, 2022 (JP) 2022-201597

(51) Int. Cl. H10H 20/856; H10H 20/01; H10H 20/85; H10H 20/855; H10H 29/14

(52) U.S. Cl. CPC H10H 20/856; H10H 20/0363; H10H 20/8502; H10H 20/855; H10H 29/142

(57) ABSTRACT

This light emitting device comprises: a base; at least one first light emitting element that is disposed on the base and emits light from an upper surface and a lateral surface thereof; a reflective member disposed in a vicinity of the at least one first light emitting element; and a lens that overlaps the at least one first light emitting element in a top view, wherein a shape of the lens in the top view is an elliptical shape having a major axis in an x direction and a minor axis in a y direction orthogonal to the x direction, and, regarding a region of the reflective member overlapping the lens, an area size of a portion of the region on the −y direction side of the major axis is larger than an area size of a portion of the region present on the +y direction side of the major axis in the top view.

### TECHNICAL FIELD

The present disclosure relates to a light emitting device and a display device.

### BACKGROUND ART

As light emitting devices including a semiconductor light emitting element such as a light emitting diode (LED) light emitting devices or the like, a cannonball-type (lamp-type) light emitting device, a surface mount device-type (SMD-type) light emitting device and the like are known. A light emitting device that emits highly intense light in a forward direction is used for, for example, a large display device such as, for example, an LED display device, in which light emitting devices acting as pixels are arranged in a matrix.

For example, Patent Document No. 1 discloses a surface mount device-type LED light emitting device including lenses on a light-emitting surface side. Patent Document No. 1 discloses a light emitting device including three light emitting elements (LED chips) each disposed at a center of a cup (cavity) having an elliptical recessed surface. An inner surface of the cup is covered with a reflective material. The light emitting device described in Patent Document No. 1 may be used as a display device installed outdoors.

### CITATION LIST

### Patent Literature

Patent Document No. 1: United States Patent Application Publication No. 2020/0176643

### SUMMARY OF INVENTION

### Technical Problem

Embodiments provided as examples by the present disclosure provide a light emitting device capable of effectively using light emitted from light emitting elements. Embodiments provided as examples by the present disclosure provide a display device capable of providing a display having a high contrast ratio.

### Solution to Problem

A light emitting device according to an embodiment of the present disclosure includes a base; at least one first light emitting element disposed on the base and emitting light from an upper surface and lateral surfaces thereof; a reflective member disposed in a vicinity of the at least one first light emitting element; and a lens overlapping, as seen in a plan view, the at least one first light emitting element and the reflective member disposed in the vicinity of the at least one first light emitting element. As seen in the plan view, the lens has an elliptical shape having a major axis extending in an x direction and a minor axis extending in a y direction perpendicular to the x direction. As seen in a plan view, regarding a region of the reflective member overlapping the lens, a portion, of the region, that is present on a side of a −y direction with respect to the major axis has an area size larger than an area size of a portion, of the region, that is present on a side of a +y direction with respect to the major axis.

A display device according to an embodiment of the present disclosure includes a plurality of light emitting devices arranged in a matrix including rows and columns. The plurality of light emitting devices are each the above-described light emitting device. The plurality of light emitting devices are arranged so as to form the rows in an x direction and to form the columns in a y direction.

### Advantageous Effects of Invention

An embodiment of the present disclosure provides a light emitting device capable of effectively using light emitted from light emitting elements. Another embodiment of the present disclosure provides a display device capable of providing a display having a high contrast ratio.

### BRIEF DESCRIPTION OF DRAWINGS

FIG. 1 is a schematic perspective view of a light emitting device 1000A in an embodiment according to the present disclosure.

FIG. 2A is a schematic side view of the light emitting device 1000A as seen in a +y direction.

FIG. 2B is a schematic side view of the light emitting device 1000A as seen in a −x direction.

FIG. 3A is a schematic plan view of the light emitting device 1000A.

FIG. 3B is a schematic plan view of a resin package 100 of the light emitting device 1000A.

FIG. 3C is a cross-sectional view of the resin package 100 of the light emitting device 1000A taken along line 3C-3C in FIG. 3B.

FIG. 3D is a cross-sectional view of the resin package 100 of the light emitting device 1000A taken along line 3D-3D in FIG. 3B.

FIG. 4 is a schematic plan view of a light emitting device 1000B in an embodiment according to the present disclosure.

FIG. 5 is a schematic plan view of a light emitting device 1000C in an embodiment according to the present disclosure.

FIG. 6 is a schematic plan view of a light emitting device 1000D in an embodiment according to the present disclosure.

FIG. 7A is a schematic plan view of a light emitting device 1000E in an embodiment according to the present disclosure.

FIG. 7B is a schematic plan view of the resin package 100 of a light emitting device 1000F in an embodiment according to the present disclosure.

FIG. 8A is a schematic perspective view illustrating a step of forming reflective members and light absorbing members of a light emitting device in an embodiment according to the present disclosure.

FIG. 8B is a schematic perspective view illustrating the step of forming the reflective members and the light absorbing members of the light emitting device in an embodiment according to the present disclosure (continued from FIG. 8A).

FIG. 8C is a schematic perspective view illustrating the step of forming the reflective members and the light absorbing members of the light emitting device in an embodiment according to the present disclosure (continued from FIG. 8B).

FIG. 9 is a schematic plan view of a display device 2000 in an embodiment according to the present disclosure.

FIG. 10 is a schematic partial cross-sectional view of the display device 2000.

FIG. 11A is a schematic cross-sectional view of a light emitting device 1000G in an embodiment according to the present disclosure.

FIG. 11B is an enlarged schematic partial cross-sectional view of the light emitting device 1000G.

FIG. 11C is a graph showing the relative luminous intensity vs. directivity angle relationship of the light emitting device 1000G.

FIG. 11D is a schematic plan view of the light emitting device 1000G.

FIG. 12 is a schematic plan view of a light emitting device 1000H in an embodiment according to the present disclosure.

FIG. 13 is a schematic plan view of a light emitting device 1000J in an embodiment according to the present disclosure.

FIG. 14A is a schematic plan view of a light emitting device 1000K in an embodiment according to the present disclosure.

FIG. 14B is a schematic plan view of a light emitting device 1000L in an embodiment according to the present disclosure.

FIG. 15A is a schematic plan view of a light emitting device 1000M in an embodiment according to the present disclosure.

FIG. 15B is an enlarged schematic partial perspective view of the light emitting device 1000M.

FIG. 15C is an enlarged schematic partial cross-sectional view of the light emitting device 1000M.

### DESCRIPTION OF EMBODIMENTS

Hereinafter, embodiments of the present disclosure will be described with reference to drawings when necessary. Note that a light emitting device and a display device described below are provided for embodying the technological philosophy of the present disclosure, and the present disclosure is not limited to any of the followings unless otherwise specified. Specificities described in one embodiment are also applicable to other embodiments and modifications. The sizes, the positional relationship and the like of components shown in the drawings may be exaggerated for clarifying the description.

In the following description, components having substantially the same functions will be represented by a common reference sign, and overlapping descriptions thereof may be omitted. Alternatively, components not referred to in the description may not be represented by any reference sign. In the following description, terms representing specific directions or positions (e.g., “top”, “bottom”, “right”, “left” and other terms including such terms) may be used. These terms are merely used for easy understanding of relative directions or positions in the drawings referred to. As long as the relative direction or the positional relationship of components represented by the terms of “top”, “bottom” and the like in the drawings referred to is the same, the components shown in the drawings referred to do not need to be disposed in the same positional relationship in drawings other than those in the present disclosure, in actual products, in actual production devices or the like. In the present disclosure, the expression “substantially parallel” encompasses a case where two lines, sides, planes or the like make an angle of about 0°±about 5°, unless otherwise specified. In the present disclosure, the expression “substantially vertical” or “substantially perpendicular” encompasses a case where two lines, sides, planes or the like make an angle of about 90°±about 5°, unless otherwise specified.

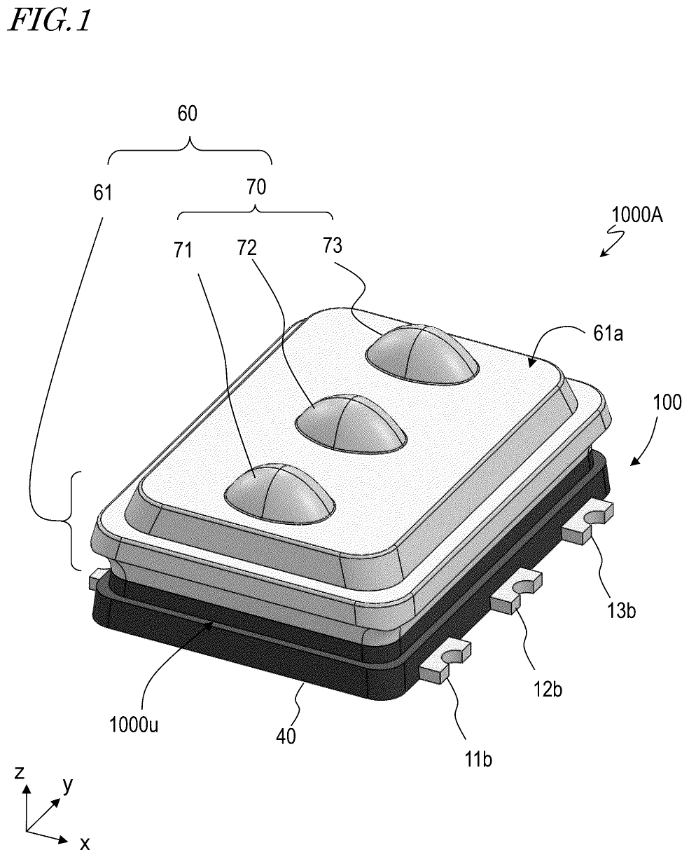

Positions of the components of the light emitting devices and the display devices may be described by use of an xyz orthogonal coordinate system. An x axis, a y axis and a z axis perpendicular to each other as shown in FIG. 1 may also be used in the other drawings in the present disclosure to show these directions. A light emitting device emits light in a +z direction. Regarding an elliptical lens disposed so as to overlap the light emitting element as seen in a plan view, a direction parallel to a major axis of the elliptical lens is represented by the x axis and a direction parallel to a minor axis of the elliptical lens is represented by the y axis. In the case where the light emitting device includes a plurality of light emitting elements, the plurality of light emitting elements are arranged in the y direction. In a display device including a plurality of the light emitting devices arranged in a matrix including rows and columns, the plurality of light emitting devices form rows in the x direction and form columns in the y direction.

A light emitting device according to an embodiment of the present disclosure includes a base, at least one first light emitting element disposed on the base and emitting light from an upper surface and lateral surfaces thereof, a reflective member disposed in a vicinity of the at least one first light emitting element, and a lens overlapping the at least one first light emitting element as seen in a plan view. As seen in a plan view, the lens has an elliptical shape having the major axis extending in the x axis and the minor axis extending in the y axis perpendicular to the x axis. As seen in a plan view, a region of the reflective member disposed in the vicinity of the at least one light emitting element overlaps the lens. The reflective member is disposed such that a portion, of the region, that is present on a side of the −y direction with respect to the major axis has an area size larger than an area size of a portion, of the region, that is present on a side of the +y direction with respect to the major axis.

The reflective member included in the light emitting device according to an embodiment of the present disclosure is applicable to light emitting devices described in Japanese Patent Applications Nos. 2022-083491 and 2022-083492 filed by the present Applicant, and also to various other light emitting devices. In the following, an example in which the reflective member included in the light emitting device according to an embodiment of the present disclosure is applied to the light emitting device described in Japanese Patent Application No. 2022-083491 or No. 2022-083492 will be described. Except for the position of the reflective member and the components that restrict the position of the reflective member, the entirety of Japanese Patent Applications Nos. 2022-083491 and 2022-083492 will be incorporated herein by reference.

### Embodiment 1

FIG. 1 is a schematic perspective view of a light emitting device 1000A in an embodiment according to the present disclosure. In a configuration shown as an example in FIG. 1, the light emitting device 1000A has an external shape that is generally rectangular as seen in a plan view. Each of sides of the rectangular shape is substantially parallel to the x axis or the y axis shown in the figure. The z axis is substantially vertical to the x axis and the y axis. The external shape of the light emitting device 1000A does not need to be rectangular as seen in a plan view. Note that a “rectangle” is a quadrangle in which all the interior angles are 90°.

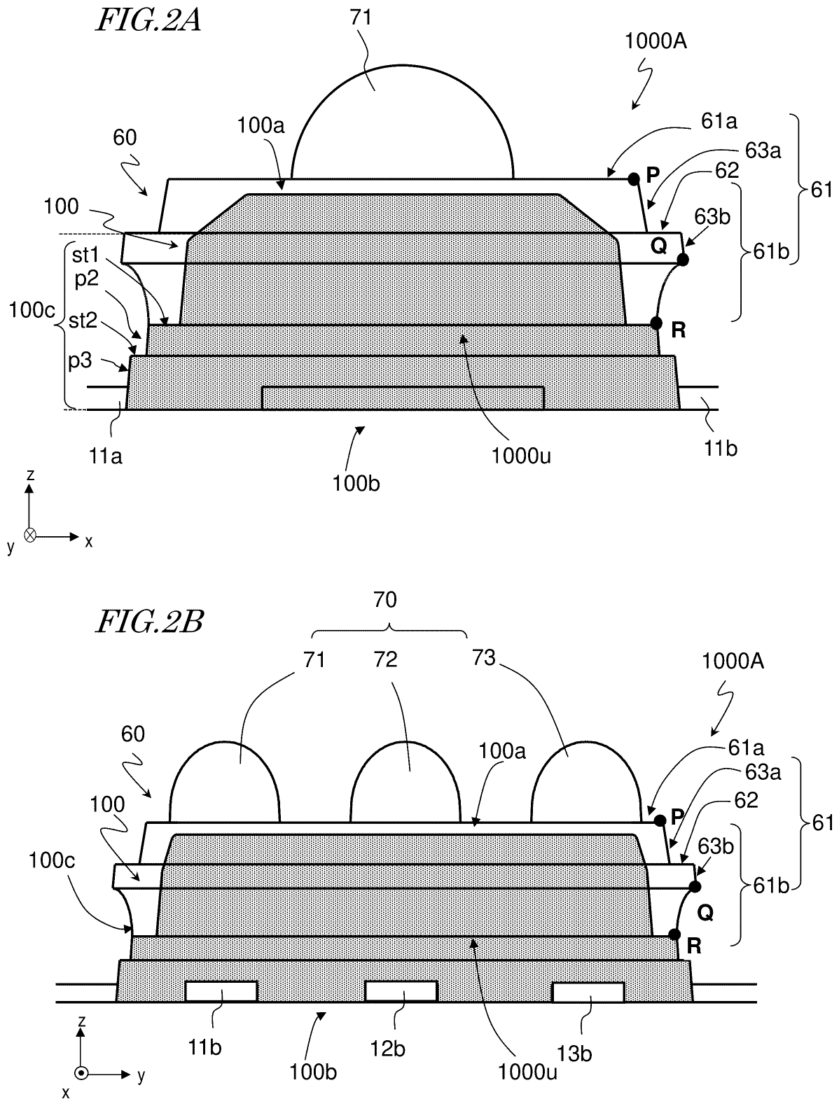

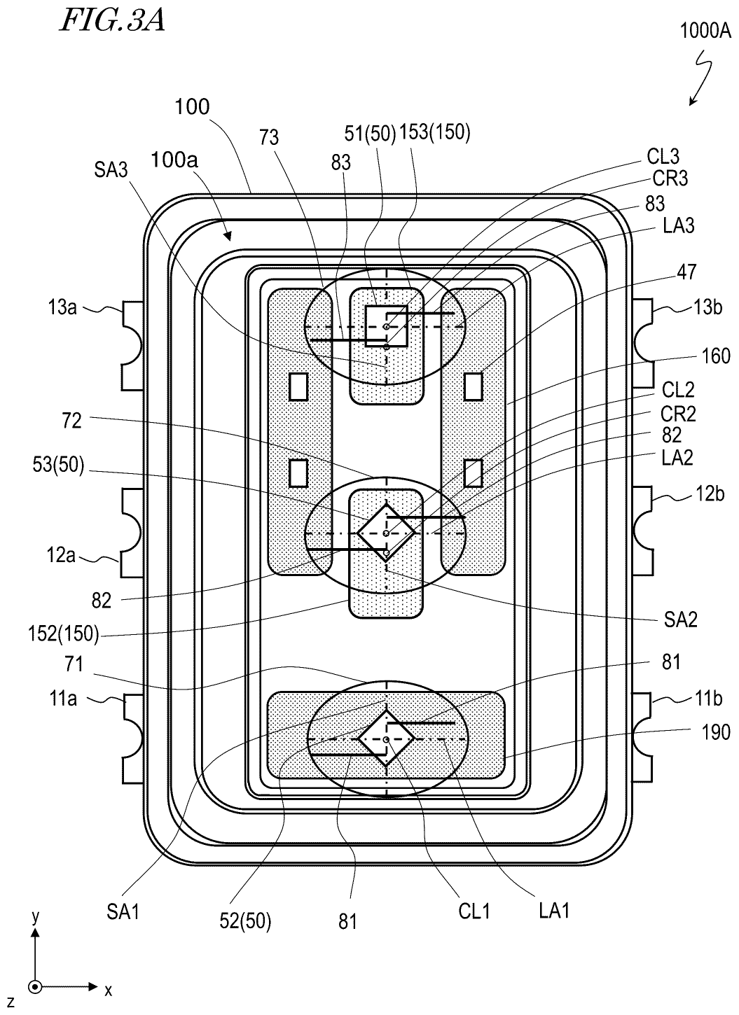

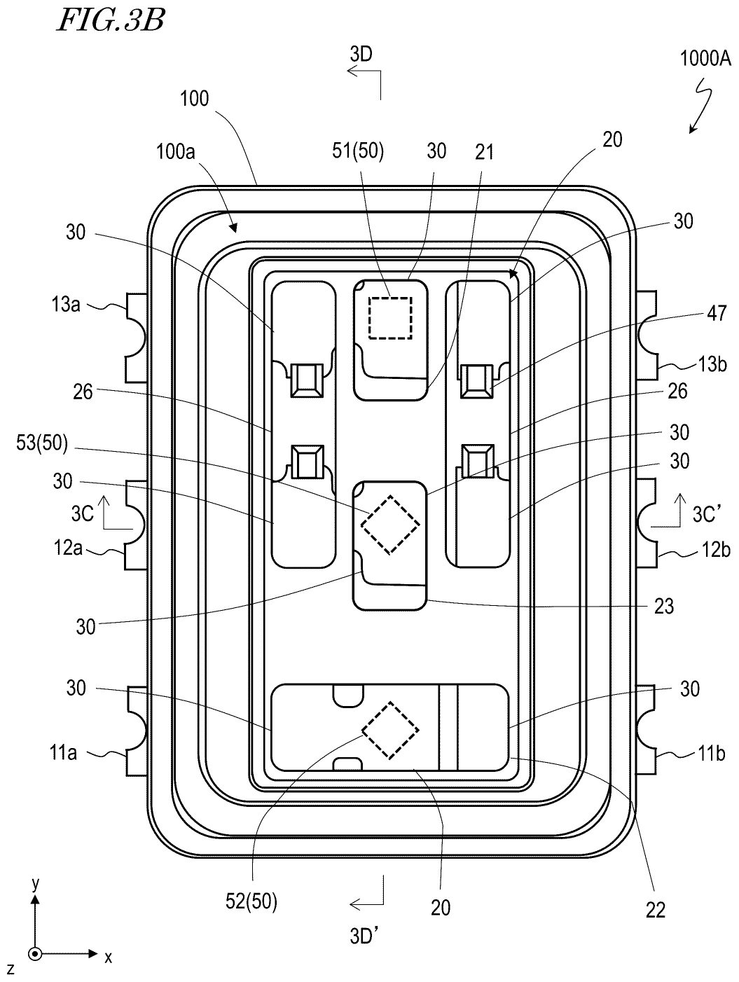

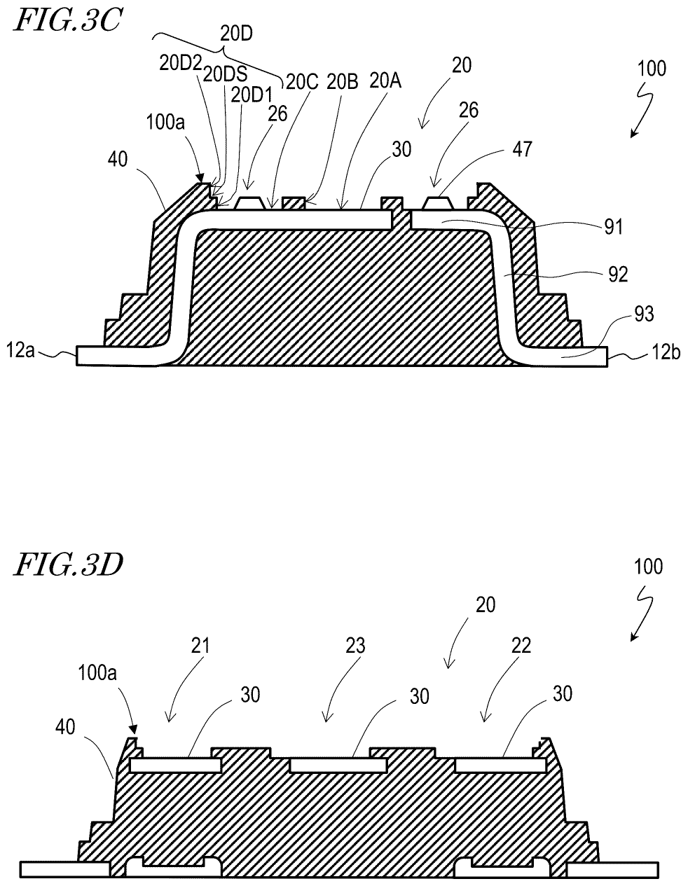

FIG. 2A is a schematic side view of the light emitting device 1000A as seen in the +y direction. FIG. 2B is a schematic side view of the light emitting device 1000A as seen in the −x direction. FIG. 3A is a schematic see-through plan view of the light emitting device 1000A. FIG. 3B is a schematic plan view of a resin package 100 of the light emitting device 1000A. FIG. 3C is a cross-sectional view of the resin package 100 taken along line 3C-3C′ in FIG. 3B. FIG. 3D is a cross-sectional view of the resin package 100 taken along line 3D-3D′ in FIG. 3B. FIG. 3C also shows protrusions 47 located beyond the cross-section.

### [Base]

The light emitting device 1000A includes the resin package 100 as a base, at least one light emitting element 50, a reflective member 150, and a lens portion 70. The base is a member on which the light emitting element is placed, for example, a resin package including a resin member and a lead. The base may include a ceramic member and a conductive member. Hereinafter, an example in which the base is the resin package 100 and the light emitting element 50 is an LED chip 50 will be described.

The light emitting device 1000A includes the base 100, a plurality of the light emitting elements 50 including a first light emitting element 51, a second emitting element 52 and a third emitting element 53, the reflective member 150, light absorbing members 160 and 190, and a mold resin portion 60. The mold resin portion 60 includes a base portion 61 sealing the plurality of light emitting elements 50 and a plurality of the lens portions 70 located on the base portion 61.

### [Resin Package 100]

The resin package 100 includes at least a pair of leads and a resin member 40 fixing the pair of leads. In the example shown in FIG. 3A, a plurality of the pairs of leads are included. In this embodiment, the resin member is, for example, the dark color resin member 40 formed of a dark color resin.

The resin package 100 includes a main surface 100a, a rear surface 100b opposite to the main surface 100a, and an outer side portion 100c located between the main surface 100a and the rear surface 100b. The rear surface 100b of the resin package 100 includes a bottom surface of the resin member 40 and a mounting surface of each of the leads that is used to secure the light emitting device 1000A to a mounting substrate. In this example, the rear surface 100b is substantially parallel to an xy plane.

As shown in FIG. 3A, the main surface 100a of the resin package 100 is quadrangular as seen in a plan view. Each of sides of the rectangular main surface 100a is substantially parallel to the x axis or the y axis. The main surface 100a may have a different shape from the quadrangular shape as seen in a plan view, and may have, for example, a generally triangular shape, a generally quadrangular shape, a generally pentagonal shape, a generally hexagonal shape, any other polygonal shape, or a shape having a curved line such as a circular shape, an elliptical shape or the like. In the case where the main surface 100a has a polygonal shape as seen in a plan view, a portion of, or all of, the corners of the polygonal shape may be rounded.

As shown in FIG. 3B through FIG. 3D, the main surface 100a of the resin package 100 includes first regions 20 respectively defined by the resin member 40 and the plurality of leads 11a though 13b. The first regions 20 are each a recessed portion including a bottom surface 20A and inner lateral surfaces 20B enclosing the bottom surface 20A. The bottom surface 20A includes an exposed region 30 of at least one of the leads. In the first regions 20, the light emitting elements 50 are disposed. The inner lateral surfaces 20B of the first regions 20 are integrally formed with the resin member 40, which forms a portion of the bottom surfaces 20A. Alternatively, the inner lateral surfaces of the first regions 20 may be formed of a material different from that of the resin member 40, which forms a portion of bottom surfaces 20C. It is sufficient that the first regions 20 allow the reflective member 150 and the light absorbing members 160 and 190 to be disposed therein. Wires may be connected in the first regions 20.

As shown in FIG. 3B, the main surface 100a includes the plurality of first regions 20. As seen in a plan view, the first regions 20 each have, for example a quadrangular shape. A portion of, or all of, the corners of the quadrangular shape may be rounded. The plurality of first regions 20 may all have the same size and the same shape, or may have different sizes or different shapes. There is no specific limitation on the size of each of the first regions 20. For example, it is sufficient that the first regions 20 each have a size sufficiently large to allow a member that joins the light emitting element 50 to a corresponding lead, among the leads 11a through 13b, to be disposed therein and also allow the reflective member 150 to be disposed therein. In the case where the first light emitting element 51 and the third light emitting element 53 disposed in the first regions 20 are of the same size, the first regions 20 may have the same size. In the case where the first light emitting element 51 and the third light emitting element 53 disposed in the first regions 20 are of different sizes, the first regions 20 may have different sizes. The plurality of first regions 20 are provided respectively in correspondence with lens portions 71 through 73. The light emitting device 1000A includes a first region 21 corresponding to the lens portion 73, a first region 22 corresponding to the lens portion 71, and a first region 23 corresponding to the lens portion 72. As seen in a plan view, the main surface 100a includes the resin member 40 between the first region 21 and the first region 23 and between the first region 22 and the first region 23. The resin member 40, which has a low coefficient of thermal expansion, is provided between the light emitting elements 50, so that an influence of a stress on the light emitting elements 50 caused during, for example, the production of the mold resin portion 60 may be decreased.

The main surface 100a of the resin package 100 further includes second regions 26 respectively defined by the resin portion 40 and the plurality of leads 11a through 13a. As shown in FIG. 3C and FIG. 3D, the second regions 26 are each a recessed portion including a bottom surface 20C and inner lateral surfaces 20D enclosing the bottom surface 20C. The second regions 26 include exposed regions 30 of the leads. It is sufficient that the second regions 26 allow the light absorbing members 160 and 190 to be disposed therein. The main surface 100a of the resin package 100 includes the second regions 26, so that different components from those in the first regions 20 may be disposed in the second regions 26. As shown in FIG. 3C, the inner lateral surfaces 20D each include a first inner lateral surface 20D1, a second inner lateral surface 20D2, and a stepped surface 20DS. The first inner lateral surface 20D1 is continuous from the bottom surface 20C. The second inner lateral surface 20D2 is continuous from the main surface 100a. The stepped surface 20DS connects the first inner lateral surface 20D1 and the second inner lateral surface 20D2 to each other. Like the first regions 20, the second regions 26 may each include the inner lateral surfaces formed of a material different from that of the resin member 40. Wires are connected in the second regions 26. As shown in FIG. 3A, the second regions 26 are adjacent to, but out of contact with, the first regions 20 as seen in a plan view. The first regions 20 are disposed between two second regions 26. The second regions 26 each have a length longer than that of each of the first regions 20 in the y direction. The second regions 26 may each have a length that is equal to, or different from, that of each of the first regions 20 in the x direction. For example, as shown in FIG. 3B, the length in the x direction of the first region 22 is longer than the length in the x direction (longer than the width) of each of the first region 21 and the first region 23.

As shown in FIG. 2A, the resin package 100 includes a first stepped surface st1 in the outer side portion 100c. The first stepped surface st1 is oriented in the same direction as the main surface 100a. The first stepped surface st1 is located closer to the rear surface 100b than a second point Q of the base portion 61. The outer side portion 100c of the resin package 100 further includes a second stepped surface st2. The second stepped surface st2 is located outer to the first stepped surface st1 as seen in a plan view. The outer side portion 100c of the resin package 100 includes a second surface p2 connecting the first stepped surface st1 and the second stepped surface st2 to each other. The outer side portion 100c of the resin package 100 includes a third surface p3 connecting the second stepped surface st2 and the rear surface 100b to each other. A recessed portion may be located at a position where the second stepped surface st2 and the second surface p2 cross each other.

### [Resin Member 40]

The resin member 40 is insulating in order to electrically insulate the light emitting elements 50 from the outside of the light emitting elements 50. It is preferred that at least a portion of the resin member 40 that is close to the main surface 100a of the resin package 100, that is, a portion located on a light emission observation side, is of a dark color such as black, gray or the like. For example, the resin member 40 may be colored to have a dark color. Alternatively, the resin member 40 may be formed of a white color-type resin with dark color ink printed thereon. Still alternatively, the resin member 40 may be formed by molding resins of two colors, that is, a dark color resin and a white color resin. At the main surface 100a of the resin package 100, the resin member 40 decreases the reflection of external light such as sunlight, indoor light or the like and thus may improve the contrast ratio between when the light emitting device 1000A is lit up and when the light emitting device 1000A is lit out. As a result, a decrease in the contrast ratio of an outdoor display may be alleviated. In this specification, the term “dark color” refers to a color having a lightness of 4.0 or lower in the Munsell color system (20 hues). There is no specific limitation on the hue, and the chromaticity may be determined in an optional manner when necessary. Preferably, the dark color has a lightness of 4.0 or lower and a chromaticity of 4.0 or lower.

It is sufficient that the resin member 40 has such a shape as to be capable of holding at least a portion of the plurality of leads 11a through 13b, and the shape of the resin member 40 is not limited to the shape shown in the figures. Preferably, the resin member 40 integrally fixes the plurality of leads (in this example, three pairs of leads).

A preferred material of the resin member 40 has a low coefficient of thermal expansion and a superb adhesiveness with the mold resin portion 60. The coefficient of thermal expansion of the resin member 40 may be generally equal to that of the mold resin portion 60, or may be smaller than that of the mold resin portion 60 in consideration of an influence of heat from the light emitting elements 50.

The resin member 40 may be formed of, for example, a thermoplastic resin. Usable thermoplastic resins include an aromatic polyamide-based resin, a polyphthalamide resin (PPA), a sulfone-based resin, a polyamideimide resin (PAI), a polyketone resin (PK), a polycarbonate resin, polyphenylenesulfide (PPS), a liquid crystal polymer (LCP), an ABS resin, a PBT resin, and the like. Such a thermoplastic resin having glass fiber incorporated thereto may be used as a thermoplastic material. Glass fiber is incorporated in this manner, so that the resin package may have a high rigidity and a high strength. In this specification, the term “thermoplastic resin” refers to a substance having a linear polymeric configuration that is softened and further subjected to liquefaction when being heated and is solidified when being cooled. Such thermoplastic resins include, for example, styrene-based, acrylic, cellulose-based, polyethylene-based, vinyl-based, polyamide-based, carbon fluoride-based resins, and the like.

Alternatively, the resin member 40 may be formed of a thermosetting resin such as, for example, a silicone resin, an epoxy resin or the like.

The resin material of the resin member 40 may have a colorant incorporated thereto. As the colorant, any of various dyes and pigments is preferably usable. Specifically, preferred colorants include Cr₂O₃, MnO₂, Fe₂O₃, carbon black, and the like. The colorant may be incorporated in an amount that is, for example, 0.3% by mass or higher and 3.5% by mass or lower, and preferably 1.0% by mass or higher and 2.5% by mass or lower, with respect to the resin material as a parent material. The resin member 40 may be formed of, for example, polyphthalamide (PPA) having 2% by mass of dark color particles such as carbon particles or the like incorporated thereto. The resin material of the resin member 40 may contain a glass filler or the like. The glass filler may be colored to be of a dark color by carbon black or the like.

[Leads 11a Through 13b]

The plurality of leads 11a through 13b each have a conductivity and acts as an electrode that supplies electric power to the corresponding light emitting element 50. The plurality of leads 11a through 13b each include the exposed region 30 exposed from the resin member 40.

In the light emitting device 1000A, the leads 11a and 11b forming a first lead pair are each bent so as to include a first portion 91 located closer to the main surface 100a of the resin package 100, a second portion 93 located closer to the rear surface 100b of the resin package 100, and a third portion 92 located between the first portion 91 and the second portion 93 and extending along the outer side portion 100c of the resin package 100. At least a portion of the second portion 93 of each of the leads 11a and 11b is exposed to the rear surface 100b of the resin package 100, and acts as a mounting surface when the light emitting device 1000A is secured to the mounting substrate. It is preferred that the mounting surface of each of the leads 11a and 11b is flush with the bottom surface of the resin member 40. The leads 12a and 12b forming a second lead pair, and the leads 13a and 13b forming a third lead pair have the same configuration as that of the first lead pair.

As shown in FIG. 3A, on the main surface 100a of the resin package 100 of the light emitting device 1000A, the first leads 11a and 11b, the second leads 12a and 12b and the third leads 13a and 13b are arranged in, for example, the y direction. On the main surface 100a, ends of the two leads forming each lead pair are out of contact with, and opposite to, each other. There is no specific limitation on the positions, the shapes, the number or the like of the leads used in the light emitting device 1000A. For example, the number of leads may be two or greater. One common lead may be provided instead of the leads 11b, 12b and 13b. Among the first light emitting element 51 through the third light emitting element 53 provided as the light emitting elements 50, two or more may be connected to such a common lead.

The leads 11a through 13b each include, for example, a base substrate and a metal layer covering a surface of the base substrate. The base substrate contains a metal material such as, for example, copper, aluminum, gold, silver, iron, nickel, an alloy thereof, phosphor bronze, iron-containing copper, or the like. Such a material may be provided in the form of a single layer or a stack configuration (e.g., clad material). The metal layer is, for example, a plated layer. The metal layer may contain, for example, silver, aluminum, nickel, palladium, rhodium, gold, copper, an alloy thereof, or the like. The leads 11a through 13b each include such a metal layer, and thus may have an improved light reflectance and/or an improved joining property with a metal wire or the like described below. For example, the leads 11a through 13b may be formed of a copper alloy substrate and a silver-plated layer covering a surface of the copper alloy substrate.

### [Light Emitting Elements 50]

At least one light emitting element 50 is disposed on the exposed region 30 of the first region 20. In the example shown in FIG. 3A, the light emitting device 1000A includes the first light emitting element 51, the second emitting element 52, and the third emitting element 53. The first light emitting element 51 is disposed on the exposed region 30 of the lead 13a in the first region 21. The first light emitting element 51 is electrically connected with the leads 13a and 13b via wires 83. The second light emitting element 52 is disposed on the exposed region 30 of the lead 11a in the first region 22. The second light emitting element 52 is electrically connected with the leads 11a and 11b via wires 81. The third light emitting element 53 is disposed on the exposed region 30 of the lead 12a in the first region 23. The third light emitting element 53 is electrically connected with the leads 12a and 12b via wires 82.

The light emitting elements 50 are, for example, rectangular as seen in a plan view. There is no specific limitation on the size of each of the light emitting elements 50. The vertical and horizontal lengths of each of the light emitting elements 50 are, for example, 100 μm or longer and 1000 μm or shorter. For example, the light emitting elements 50 each have a square shape having a side of 320 μm as seen in a plan view.

The light emitting elements 50 include a light emitting element emitting light from an upper surface and lateral surfaces thereof. The “light emitting element emitting light from an upper surface and lateral surfaces thereof” refers to a light emitting element that includes, for example, a light-transmissive substrate and a light emitting portion and emits light from the light emitting portion through the light-transmissive substrate. The light emitting elements 50 may further include a light emitting element emitting light substantially only from an upper surface thereof. The “light emitting element emitting light substantially only from an upper surface thereof” refers to a light emitting element that does not include, for example, a light-transmissive substrate and emits light from the light emitting portion with no use of the light-transmissive substrate. The light from the light emitting element including the light-transmissive substrate is easily retrieved from the lateral surfaces as well as from the upper surface. Therefore, the light emitting element including the light-transmissive substrate allows the light to be retrieved sideways more easily than the light emitting element not including the light-transmissive substrate. For example, the first light emitting element 51 and the third light emitting element 53 are each a light emitting element that emits light from the upper surface and the lateral surfaces thereof, and the second light emitting element 52 is a light emitting element that emits light substantially only from the upper surface thereof. Note that all the plurality of light emitting elements 50 may emit light from the lateral surfaces as well as from the upper surface thereof.

In the example shown in FIG. 3B, as seen in a plan view, the first light emitting element 51 is disposed on the side of the +y direction in the first region 21. The center of the first light emitting element 51 does not match the center of the first region 21. The first light emitting element 51 is a blue light emitting element. The third light emitting element 53 is disposed in a positional relationship similar to that of the first light emitting element 51. The third light emitting element 53 is a green light emitting element. As seen in a plan view, the second light emitting element 52 is disposed at the center of the first region 22. The second light emitting element 52 is a red light emitting element.

Note that the third light emitting element 53 may be a blue light emitting element emitting blue light whereas the first light emitting element 51 may be a green light emitting element emitting green light. For example, a red light emitting element emits light having a wavelength of 610 nm or longer and 700 nm or shorter, a blue light emitting element emits light having a wavelength of 430 nm or longer and 490 nm or shorter, and a green light emitting element emits light having a wavelength of 495 nm or longer and 565 nm or shorter. A “wavelength” refers to an emission peak wavelength of light that is emitted from each of the light emitting elements.

The light emission wavelengths of the plurality of light emitting elements 50 are selected such that, for example, white light is provided when all the plurality of light emitting elements 50 are lit up. Use of the plurality of light emitting elements 50 emitting red light, blue light and green light realizes a full-color display. The number of the plurality of light emitting elements 50 and the combination of the colors of light emission are examples, and are not limited to those in this example. The wavelengths of the plurality of light emitting elements 50 may be different from each other, or the plurality of light emitting elements 50 may include light emitting elements 50 emitting light of the same wavelength.

A light emitting element emitting blue light or green light may use ZnSe or a nitride-based semiconductor (In_{X}Al_{Y}Ga_{1-X-y}N, 0≤X, 0≤Y, X+Y≤1). For example, a light emitting element including a support substrate of sapphire or the like and a semiconductor layer containing GaN formed on the support substrate may be used. A light emitting element emitting red light may use, for example, a Ga—As-based, an AlInGaP-based, or an AlGaAs-based semiconductor. For example, a light emitting element including a support substrate of silicon, aluminum nitride, sapphire or the like and a semiconductor layer containing AlInGaP formed on the support substrate may be used. A light emitting element formed of materials other than these may be used. The composition, the color of light emission, the size, the number and the like of the light emitting elements may be appropriately selected in accordance with the purpose of use.

A fluorescent substance converting the wavelength of light emitted from a light emitting element formed of a nitride-based semiconductor or the like may be disposed around the light emitting element. In this case, any optional light emission may be provided. In this specification, the expression “light emitting element 50” encompasses a light emitting element formed of a nitride-based semiconductor or the like and also an element including a light emitting element and a fluorescent substance. Usable fluorescent substances include, specifically, yttrium-aluminum-garnet activated by cerium, lutetium-aluminum-garnet activated by cerium, nitrogen-containing calcium aluminosilicate activated by europium and/or chromium (calcium may be partially replaced with strontium), SiAlON activated by europium, silicate activated by europium, strontium aluminate activated by europium, potassium fluorosilicate activated by manganese, and the like. In an example, the first light emitting element 51, the second light emitting element 52 and the third light emitting element 53 may all include a semiconductor chip emitting blue light. In this case, at least two of these light emitting elements may each include a fluorescent substance around the semiconductor chip, so that the first light emitting element 51, the second light emitting element 52 and the third light emitting element 53 may emit light of different colors from each other.

The first light emitting element 51, the second light emitting element 52 and the third light emitting element 53 may each be joined with the exposed region 30 of any of the plurality of leads 11a through 13b by a joining member such as a resin, solder, a conductive paste or the like.

As shown in FIG. 3A and FIG. 3B, the first light emitting element 51 through the third light emitting element 53 are respectively disposed on the exposed regions 30 of three different leads (in this example, the leads 11a, 12a and 13a). With this arrangement, heat dissipation paths of the first light emitting element 51, the second light emitting element 52 and the third light emitting element 53 may be separated from each other. Therefore, the heat generated by each light emitting element 50 may be dissipated efficiently.

In the example shown in FIG. 3A and FIG. 3B, the wires 83 electrically connecting the first light emitting element 51 with the leads 13a and 13b, and the wires 82 electrically connecting the third light emitting element 53 with the leads 12a and 12b, are connected with the second regions 26 (wire connection regions). The wires 81 electrically connecting the second light emitting element 52 with the leads 11a and 11b are connected in the first region 22.

The wires 81 through 83 may each be a metal wire formed of gold, silver, copper, platinum, aluminum or an alloy thereof. Among these metal wires, a gold wire having a superb extendibility and a gold-silver alloy wire having a higher reflectance than that of the gold wire are preferably usable.

### [Reflective Members 150]

As shown in FIG. 3A, as seen in a plan view, the reflective members 150 are disposed in the vicinity of the first light emitting element 51 and the third light emitting element 53. The reflective members 150 reflect the light emitted from the lateral surfaces of the first light emitting element 51 and the third light emitting element 53 and direct the light in the +Z direction of the light emitting elements 50. With this arrangement, the light utilization factor of the light emitted from the first light emitting element 51 and the third light emitting element 53 may be improved.

In this specification, the expression “the reflective member 150 is disposed in the vicinity of the first light emitting element 51” refers to that the reflective member 150 is disposed close to the lateral surfaces of the first light emitting element 51 as seen in a plan view. The reflective member 150 may or may not be in direct contact with the lateral surfaces of the first light emitting element 51. Preferably, the reflective member 150 is in direct contact with the lateral surfaces of the first light emitting element 51. More preferably, the reflective member 150 encloses the lateral surfaces of the first light emitting element 51 as seen in a plan view. Preferably, the reflective member 150 is provided in contact with all the lateral surfaces of the first light emitting element 51. With this arrangement, the reflective member 150 may reflect the light emitted from the lateral surfaces of the first light emitting element 51 and thus make it difficult for the light from the lateral surfaces of the first light emitting element 51 to be emitted outside. Therefore, the light is emitted mainly from the upper surface of the first light emitting element 51. Regarding a decrease in the size of the lens portion 70, most of the light emitted from the lateral surfaces of the first light emitting element 51 is totally reflected by the lens portion 70. Therefore, in the case where the amount of the light emitted from the lateral surfaces of the first light emitting element 51 is decreased by the reflective member 150 and the light is mainly emitted from the upper surface of the first light emitting element 51, the amount of the light totally reflected by the lens 70 is decreased. In this manner, the size of the lens 70 may be decreased. The above description is made by way of the first light emitting element 51. The same is applicable to the third light emitting element 53.

The reflective members 150 are disposed in, for example, the first regions 20 formed in the main surface 100a of the resin package 100. For example, the reflective members 150 may be disposed in the entirety of the first regions 20 so as to cover the bottom surfaces 20A and the inner lateral surfaces 20B of the first regions 20. In this case, the first regions 20 do not have a function of reflecting the emitted light. As shown in FIG. 3A, the reflective members 150 may be disposed so as to overlap the exposed regions 30. The reflective members 150 do not need to be disposed on the entirety of the bottom surfaces 20A of the first regions 20 and may expose a portion of the first regions 20. Alternatively, for example, the first light emitting element 51 and the third light emitting element 53 each having a lateral surface covered with the reflective member 150 may be prepared and disposed. With this arrangement, an area size of a region, of the bottom surface 20A of each first region 20, where the reflective member 150 is disposed may be decreased. The area sizes of the regions where the reflective members 150 are disposed is decreased, so that the decrease in the contrast ratio of the light emitting device 1000A may be alleviated. For example, the area sizes of the reflective members 150 is preferably smaller than 25%, more preferably 20% or smaller, and still more preferably 15% or smaller, of the area size of the main surface 100a.

Reflective members 152 and 153 are disposed, so that the light from the lateral surfaces of the first light emitting element 51 and the third light emitting element 53 may be reflected and directed in the +z direction of the light emitting device 1000A.

The reflective members 150 are formed of, for example, a reflective resin material. The reflective resin material contains a resin as a parent material and a light-reflective substance dispersed in the resin. Usable parent materials include an epoxy resin, a silicone resin, an epoxy-modified silicone resin, a resin containing a mixture thereof, and a light-transmissive material such as glass or the like. From the point of views of light resistance and moldability, it is preferred to select an epoxy-modified silicone resin as the parent material.

Usable light-reflective substances include titanium oxide, silicon oxide, zirconia, yttrium oxide, yttria-stabilized zirconia, potassium titanate, aluminum oxide, aluminum nitride, boron nitride, mullite, and the like. In this embodiment, for example, titanium oxide is used. It is preferred that the light-reflective substance is contained in the reflective members 150 at a concentration of 10% mass or higher and 80% by mass or lower. It is preferred that the reflective members 150 contain titanium oxide as a light-reflective substance. The reflective members 150 may contain a glass filler or the like in order to decrease the expansion and contraction caused by the heat of the resin as the parent material. It is preferred that the glass filler is contained at a concentration that is higher than 0% by mass and lower than 40% by mass. The concentrations of the light-reflective substance, the glass filler and the like are not limited to those mentioned above.

The reflective members 150 may be formed of any material that reflects the light emitted from the light emitting elements 50. It is preferred that the reflective members 150 are formed of a material having a reflectance of 80% or higher to light of a peak wavelength emitted from the light emitting elements 50. The reflective members 150 may be formed of a single layer or a multi-layer film of a metal material, or a multi-layer film including a stack of two or more types of dielectric materials (dielectric multi-layer film). As the dielectric multi-layer film, a DBR (distributed Bragg reflector) film may be used, for example.

A light-transmissive resin member may be further included between the reflective members 150/the light emitting elements 50 and the mold resin portion 60. For example, the light-transmissive resin member is disposed between the inner lateral surfaces 20D facing each other as seen in a cross-sectional view. It is preferred that the light-transmissive resin member covers a portion, of the second inner lateral surfaces 20D2, that is exposed from the light absorbing member 190. The material of the light-transmissive resin member may be formed of a material substantially the same as that of the mold resin portion 60. The light-transmissive resin member may contain a colorant. The light-transmissive resin member containing a colorant overlaps the reflective members 150, so that the contrast ratio may be further improved.

### [Lens Portions 70]

The lens portions 70 have a luminous intensity distribution function of controlling the direction and the distribution of the emitted light.

One lens portion 70 or the plurality of lens portions 70 are located. In the example shown in FIG. 3A, the light emitting device 1000A include the plurality of lens portions 70. As seen in a plan view, the plurality of lens portions 70 include a third lens portion 73 overlapping the first light emitting element 51, a first lens portion 71 overlapping the second light emitting element 52, and a second lens portion 72 overlapping the third light emitting element 53. The light emitting device 1000A includes the lens portions 70, and thus may emit highly intense light in the +z direction. The lens portions 70 may be referred to simply as “lenses”. The lens portions 70 may be integral with, or separate from, the base portion 61.

As shown in FIG. 2A and FIG. 2B, each of the plurality of lens portions 70 has a protruding shape protruding upward from an upper surface 61a of the base portion 61. Each lens portion 70 has, for example, an elliptical or circular shape as seen in a plan view. In this specification, the term “elliptical shape” or “circular shape” is not limited to referring to a geometrically strict elliptical or circular shape, but encompasses a shape similar to an elliptical or circular shape. As shown in FIG. 3A, each lens portion 70 has an elliptical shape as seen in a plan view. A major axis of the elliptical shape extends in the x direction whereas a minor axis thereof extends in the y direction. Therefore, the luminous intensity distribution of the light is broad in the x direction and narrow in the y direction. The light emitting device 1000A having such a luminous intensity distribution is preferably usable especially for a display device such as an LED display or the like. In a side view seen in the x direction or in the y direction, the lens portion 70 may have an outer perimeter formed only of a curved line, such as an elliptical arcked perimeter or an arcked perimeter, or may have an outer perimeter including a linear portion in addition to a curved portion such as an elliptical arcked portion or an arcked portion. The linear portion may be located between the curved portion and the upper surface 61a of the base portion 61. For example, the lens portion 70 may have, for example, a shape including a circular truncated cone and a portion of a sphere (e.g., a hemisphere) located thereon or a shape including an elliptical truncated cone and a portion of an ellipsoid located thereon.

Each of the plurality of lens portions 70 is located in correspondence with one of the light emitting elements 50. Each lens portion 70 has an optical axis matching the center (center of a light emitting surface) of the corresponding light emitting element 50. This arrangement may further improve the controllability on the luminous intensity distribution of the light emitting device 1000A. Note that the optical axis of each lens portion 70 does not need to match the center of the corresponding light emitting element 50.

For example, in a side view of the light emitting device 1000A seen in the x direction or in the y direction, the lens portion 70 has a shape line-symmetrical with respect to a straight line L1, which passes the apex of the lens portion 70 and is parallel to the z axis. Centers CL1 through CL3 of the lens portions 70 described below are on the straight line L1. The straight line L1 matches the optical axis of each lens portion 70. The apex of each lens portion 70 and the center of the corresponding light emitting element 50 are on the same straight line parallel to the z-axis direction. Each lens portion 70 has a radius of curvature that may be appropriately selected. For example, portions of each lens portion 70 separated by the apex thereof may have different radii of curvature, or may have the same radius of curvature.

The shape and the position of each lens portion 70 as seen in a plan view may be appropriately selected in consideration of the luminous intensity distribution property, the light gathering property and the like. The cross-sectional shape of the lens portion is not limited to a protruding shape. The lens portion may be, for example, a concave lens, a Fresnel lens or the like.

In this specification, first light from the first light emitting element 51 is transmitted through the third lens portion 73 and is emitted in the +z direction of the light emitting device 1000A. The direction and the distribution of the first light are controlled by the third lens portion 73. Similarly, second light from the second light emitting element 52 is transmitted through the first lens portion 71, and third light from the third light emitting element 53 is transmitted through the second lens portion 72. The first lens portion 71 and the second lens portion 72 respectively control the luminous intensity distribution of the second light and the third light.

The light transmitted through the third lens portion 73, the first lens portion 71 and the second lens portion 72 when the first light emitting element 51, the second light emitting element 52 and the third light emitting element 53 are lit up may be of the three primary color of light. In this case, a full-color display may be provided.

In the example shown in FIG. 3A, as seen in a plan view, the first lens portion 71, the second lens portion 72 and the third lens portion 73 are arranged in the y direction. As seen in a plan view, the centers of the first lens portion 71 through the third lens portion 73 may be located on a straight line substantially parallel to the y axis. The positional relationship of the lens portions 70 are not limited to that in this example. For example, the center of the lens portion located at the center among the first lens portion 71, the second lens portion 72 and the third lens portion 73 in the x direction or the y direction does not need to be located on a line connecting the centers of the other two lens portions.

The lens portions 70 each contain a light-transmissive parent material. It is preferred that each lens portion 70 has a light transmittance of 90% or higher at a peak wavelength of the corresponding light emitting element 50 among the plurality of light emitting elements 50. This arrangement may further improve the light retrieval efficiency of the light emitting device 1000A.

Preferably usable parent materials for the lens portions 70 include an epoxy resin, a urea resin, a silicone resin, a modified silicone resin such as an epoxy-modified silicone resin or the like, a highly weather resistant and highly light-transmissive thermosetting resin, highly weather resistant and highly light-transmissive glass, and the like.

In this embodiment, the lens portions 70 may have a light diffuser incorporated thereto in order to improve the light quality uniformity of the light emitting device 1000A. In the case where the light diffuser is incorporated into the lens portions 70, the light dissipated from the light emitting elements 50 is diffused and thus the non-uniformity in the intensity of the light may be suppressed. Preferably usable light diffusers include inorganic materials such as barium oxide, barium titanate, silicon oxide, titanium oxide, aluminum oxide and the like; and organic materials such as a melamine resin, a CTU guanamine resin, a benzoguanamine resin and the like.

The lens portions 70 may have any of various fillers incorporated thereto. Specific materials usable as the fillers are substantially the same as those of the light diffusers, but the fillers have a different mean particle size (D₅₀) as that of the light diffusers. In this specification, the “filler” refers to a material having a mean particle size of 100 nm or larger and 100 μm or smaller. In the case where a filler having such a particle size is incorporated into the light-transmissive resin, the variation in the chromaticity of the light emitting device 1000A may be alleviated because of a light scattering function thereof, the thermal shock resistance of the light-transmissive resin may be improved, and the internal stress of the resin may be alleviated.

Among the three light emitting elements 50 (51, 52 and 53) included in the light emitting device 1000A shown in FIG. 3A, the first light emitting element 51 and the third light emitting element 53 each emit light from the upper surface and the lateral surfaces thereof. Therefore, the reflective members 150 (152, 153) are disposed in the vicinity of the first light emitting element 51 and the third light emitting element 53.

Now, the positional relationship of the first light emitting element 51, the lens portion 73 overlapping the first light emitting element 51, and the reflective member 153 disposed in the vicinity of the first light emitting element 51 will be paid attention to. As seen in a plan view, the lens portion 73 has an elliptical shape having a major axis LA3 extending in the x direction and a minor axis SA3 extending in the y direction perpendicular to the x direction. As seen in a plan view, a region of the reflective member 153 overlaps the lens portion 73. A portion, of the region, that is present on the side of the −y direction with respect to the major axis LA3 has an area size larger than an area size of a portion, of the region, that is present on the side of the +y direction with respect to the major axis LA3. In the case where, for example, a display device used outdoors is looked up to from below, the direction in which the light emitting device 1000A is observed may occasionally be inclined in, for example, the −y direction. In this case, the observer visually recognizes the side of the +y direction of the first light emitting element 51 through the lens portion 73. The area size of the portion present on the side of the +y direction with respect to the major axis LA3 is smaller than the area size of the portion present on the side of the −y direction with respect to the major axis LA3. Therefore, the reflective member 153 present on the side of the +y direction is difficult to be visually recognized. This arrangement may alleviate the decrease in the contrast ratio of the light emitting device 1000A disposed outdoors. In the case where each lens portion 70 is circular, as seen in a plan view, an area size of a portion of the reflective member that is present on the side of the +y direction with respect to the center of the lens portion 70, and an area size of a portion of the reflective member that is present on the side of the −y direction with respect to the center of the lens portion 70, are compared against each other. As seen in a plan view, regarding the region, of the reflective member 153, that overlaps the lens portion 73, it is preferred that the total length of the region on the major axis LA3 is shorter than the total length of the region on the minor axis SA3. In the case where the total length of the region on the major axis LA3 is shorter than the total length of the region on the minor axis SA3, a situation is alleviated where the reflective member 153 is visually recognized as being enlarged by the lens portion 73, and thus the contrast ratio of the light emitting device 1000A may be further improved.

The length of the reflective member 153 in the x direction (first direction) is shorter than the length of the major axis LA3 of the lens portion 73. The center of the first light emitting element 51 matches the center CL3 of the lens portion 73. A center CR3 of the reflective member 153 is shifted in the y direction (second direction) with respect to the center CL3 of the lens portion 73. The center CR3 of the reflective member 153 overlaps the lens portion 73. The “center” is the geometrical center of gravity as seen in a plan view. For example, the reflective member 153 is the geometrical center of gravity of the first region 20 as seen in a plan view. In the example shown in FIG. 3A, the center CL3 of the lens portion 73 is located at an intersection of the major axis LA3 and the minor axis SA3. The length of the reflective member 153 in the y direction (second direction) may be longer than the length of the minor axis SA3 of the lens portion 73. The length of the reflective member 153 in the x direction (first direction) may be shorter than the length thereof in the y direction (second direction).

Now, the positional relationship of the third light emitting element 53, the lens portion 72 overlapping the third light emitting element 53, and the reflective member 152 disposed in the vicinity of the third light emitting element 53 will be paid attention to. As seen in a plan view, the lens portion 72 has an elliptical shape having a major axis LA2 extending in the x direction and a minor axis SA2 extending in the y direction perpendicular to the x direction. As seen in a plan view, a region of the reflective member 152 overlaps the lens portion 72. A portion, of the region, that is present on the side of the −y direction with respect to the major axis LA2 has an area size larger than an area size of a portion, of the region, that is present on the side of the +y direction with respect to the major axis LA2. This arrangement may alleviate the decrease in the contrast ratio of the light emitting device 1000A disposed outdoors.

The length of the reflective member 152 in the x direction (first direction) is shorter than the length of the major axis LA2 of the lens portion 72. The center of the third light emitting element 53 matches the center CL2 of the lens portion 72. A center CR2 of the reflective member 152 is shifted in the y direction (second direction) with respect to the center CL2 of the lens portion 72. The center CR2 of the reflective member 152 overlaps the lens portion 72. This arrangement alleviates a situation where the reflective member 152 is visually recognized as being enlarged by the lens portion 72, and thus the contrast ratio of the light emitting device 1000A may be further improved.

Among the three light emitting elements 50 included in the light emitting device 1000A, the second light emitting element 52 emits light only from the upper surface thereof. Therefore, there is no need to locate the reflective member 150 in the vicinity of the second light emitting element 52. It is preferred that the light absorbing member 190 is disposed in the vicinity of the second light emitting element 52. Provision of the light absorbing member 190 may decrease the reflection by the leads 11a and 11b, and thus may alleviate the decrease in the contrast ratio. The light absorbing member 190 is preferably disposed such that the leads 11a and 11b are at least difficult to be visually recognized, and is more preferably disposed such that the leads 11a and 11b are not visually recognized. For example, the light absorbing member 190 is disposed so as to cover the bottom surface 20C and at least a portion of the first inner lateral surfaces 20D1 of the first region 20. The light absorbing member 190 may cover the entirety of the first inner lateral surfaces 20D1, a portion or the entirety of the stepped surface 20DS, and a portion of the second inner lateral surfaces 20D2. The light absorbing member 190 may be formed of a resin material and a colorant substantially the same as those of the resin member 40. For example, the light absorbing member 190 may be formed of a resin material containing an epoxy-modified silicone resin and a glass filter, colored with carbon black, incorporated into the epoxy-modified silicone resin. The colored glass filter is contained in the resin material as a parent material at a content of, for example, 1% by mass or higher and 5% by mass or lower, and preferably 2% by mass or higher and 4% by mass or lower. It is preferred that the light absorbing member 190 has a lightness of 4.0 or lower and a chromaticity of 4.0 or lower in the Munsell color system (20 hues), like the resin material 40 of a dark color.

The center of the second light emitting element 52 matches the center CL1 of the lens portion 71. The center of the light absorbing member 190 also matches the center CL1 of the lens portion 71.

In the example shown in FIG. 3A and FIG. 3B, the light absorbing members 160 are disposed in the second regions 26. Provision of the light absorbing members 160 may decrease the reflection by the leads 12a through 13b. The light absorbing members 160 may be formed of a material substantially the same as that of the light absorbing member 190.

As seen in a plan view, the light emitting device 1000A includes the plurality of the protrusions 47 disposed in the second regions 26. The protrusions 47 are each a portion of the resin member 40 of the resin package 100. The protrusions 47 are each disposed to be out of contact with the inner lateral surfaces defining the corresponding second region 26. The plurality of protrusions 47 are disposed to be out of contact with each other. Upper surfaces of the light emitting elements 50 are located at a level higher than that of upper surfaces of the protrusions 47. The upper surfaces of the protrusions 47 may have a level equal to, or different from, that of upper surfaces of the inner lateral surfaces of the first regions 20.

At least a portion of a lateral surface of each protrusion 47 is in contact with the light absorbing member 160. As shown in FIG. 3A, the plurality of protrusions 47 are disposed, and thus the light absorbing members 160 each have a plurality of holes corresponding to the plurality of protrusions 47. The upper surface of each protrusion 47 is exposed from the light absorbing member 160. Note that the upper surface of each protrusion 47 may or may not be covered with the light absorbing member 160.

The light absorbing members 160 may be disposed in the second regions 26 other than regions thereof where the protrusions 47 are disposed. This arrangement may decrease the volume of the light absorbing members 160. Therefore, an influence of a stress caused during the production or the mounting of the light emitting device 1000A may be decreased. For example, a stress that is applied to a joining portion of the wires and the leads, by a change in the volume of each light absorbing member 160, may be decreased.

It is preferred that as seen in a plan view, each protrusion 47 is disposed such that a portion thereof overlaps the corresponding lead. This arrangement may increase contact areas between the leads 12a through 13b and the resin member 40 in the resin package 100. Note that the protrusions 47 may be omitted from the light emitting device 1000A. In the case where the protrusions 47 are omitted, it is easy to locate the light absorbing members in the second regions 26.

In the example shown in FIG. 2A and FIG. 2B, the mold resin portion 60 further includes the base portion 61. The base portion 61 seals the light emitting elements 50. The base portion 61 includes the upper surface 61a and the lateral surface portion 61b. The upper surface 61a is located at a level higher than that of the main surface 100a of the resin package 100. The upper surface 61a is a plane including start points from which the lens portions 70 are formed. The lateral surface portion 61b covers a portion of an outer side portion 100c of the resin package 100 in a direction from the upper surface 61a of the base portion 61 toward the rear surface 100b of the resin package 100. The lateral surface portion 61b continuously covers a region from the upper surface 61a of the base portion 61 to a portion of the outer side portion 100c of the resin package 100. For example, it is preferred that a lowermost end of the base portion 61 in the −z direction is located at a level higher than that of a portion, of the outer side portion 100c, where the plurality of leads 11a through 13b are exposed, and that the mold resin portion 60 are not in direct contact with any of the plurality of leads 11a through 13b. With such a preferred arrangement, the mold resin portion 60 is not located such that a portion thereof partially covers the mounting surfaces of the leads 11a through 13b. Therefore, a situation may be alleviated where the mold resin portion 60 decreases the area size of the mounting surfaces. The lens portions 70 and the base portion 61 may be formed of the same material as each other.

Referring to FIG. 2A, which is a side view as seen in the y direction of the main surface 100a, in this specification, an outermost point P of the upper surface 61a of the base portion 61 will be referred to as a “first point”, an outermost point Q of the lateral surface portion 61b of the of the base portion 61 will be referred to as a “second point”, and an outermost point R among points where the outer side portion 100c of the resin package 100 and the lateral surface portion 61b of the base portion 61 contact each other will be referred to as a “third point”.

The first point P is located closer to the lens portions 70 than the second point Q, and the second point Q is located outer to the third point R. The second point Q is located outer to the first point P. The third point R may be located inner or outer to the first point P.

As shown in FIG. 2A and FIG. 2B, a portion, of the lateral surface portion 61b of the base portion 61, that is between the first point P and the second point Q includes a base stepped surface 62. The lateral surface portion 61b of the base portion 61 includes a first inclining surface 63a connecting the point P and the base stepped surface 62 to each other, and a second inclining surface 63b connecting the base stepped surface 62 and the point Q to each other. The main surface 100a of the resin package 100 is at a level lower than that of the upper surface 61a of the base portion 61, and is higher than that of the base stepped surface 62. The base stepped surface 62 is located at a level lower than that of the main surface 100a of the resin package 100. The base stepped surface 62 is located around an outer circumference of the base portion 61. The first inclining surface 63a and the second inclining surface 63b are inclined with respect to the rear surface 100b. The first inclining surface 63a makes, with the xy plane, an angle of, for example, 5° or larger and 45° or smaller. The second inclining surface 63b makes, with the xy plane, an angle of, for example, 5° or larger and 45° or smaller. The angle made by the first inclining surface 63a and the xy plane, and the angle made by the second inclining surface 63b and the xy plane, may be equal to each other or different from each other. Note that the portion, of the lateral surface portion 61b of the base portion 61, that is between the first point P and the second point Q may be straight (that is, may be a line segment connecting the first point P and the second point Q to each other).

The portion, of the lateral surface portion 61b of the base portion 61, that is between the second point Q and the third point R is curved in a recessed manner. As shown in FIG. 2A, the portion, of an outer lateral surface of the lateral surface portion 61b of the base portion 61, that is between the second point Q and the third point R is entirely curved in a protruding manner toward the outer side portion 100c of the resin package 100. With this arrangement, a situation may be effectively alleviated where the water-proof resin disposed on the lateral surfaces of the light emitting device 1000A rises from the rear surface 100b of the resin package 100 and reaches the upper surface 61a of the base portion 61.

There is no specific limitation on the surface roughness of the base portion 61. It is preferred that the base portion 61 has a large surface roughness in order to decrease a glitter at the upper surface 61a of the base portion 61. It is preferred that a portion, of the upper surface 61a of the base portion 61, that overlaps at least the reflective members 150 as seen in a plan view has a surface roughness larger than that of the lens portions 70. This arrangement may further improve the contrast ratio of the light emitting device 1000A. A portion, of the upper surface 61a of the base portion 61, that does not overlap any of the plurality of lens portions 70 as seen in a plan view has a surface roughness larger than that of the lens portions 70. The surface roughness of the base portion 61 is thus large, so that external light such as sunlight or the like may be scattered at a surface of the base portion 61 and thus the reflection intensity may be suppressed. With this arrangement, the contrast ratio of the light emitting device 1000A caused by the reflection of the external light may be made difficult to occur. It is preferred that the portion, of the upper surface 61a of the base portion 61, that overlaps at least the reflective members 150 as seen in a plan view is roughened. That is, the base portion 61 is roughened, and thus the portion, of the upper surface 61a of the base portion 61, that overlaps the reflective members 150 is made matte. It is more preferred that the portion, of the upper surface 61a of the base portion 61, that does not overlap any of the plurality of lens portions 70 as seen in a plan view is roughened. The first inclining surface 63a and the second inclining surface 63b of the lateral surface portion 61b of the base portion 61 may or may not be roughened. For example, regions, of the upper surface 61a of the base portion 61, that are around the plurality of lens portions 70 are roughened, whereas any of the base stepped surface 62, the first inclining surface 63a and the second inclining surface 63b is not roughened. Alternatively, for example, the regions, of the upper surface 61a of the base portion 61, that are around the plurality of lens portions 70 and the base stepped surface 62 are roughened, whereas any of the first inclining surface 63a and the second inclining surface 63b is not roughened. The surface roughness of the upper surface 61a and the surface roughness of an outer surface of the lateral surface portion 61b may be equal to each other or different from each other. It is preferred that the upper surface 61a and the outer surface of the lateral surface portion 61b have an equal surface roughness from the point of view of ease of processing.

It is preferred that the upper surface 61a of the base portion 61 has an arithmetic average roughness Ra of 0.4 μm or larger and 5 μm or smaller. More preferably, Ra of the upper surface 61a is 0.8 μm or larger and 3 μm or smaller. Ra of the outer surface of the lateral surface portion 61b of the base portion 61 may be in substantially the same range as the above-mentioned range. Ra may be measured in conformity to the measuring method of surface roughness in JIS B 0601-2001. Specifically, Ra may be represented as follows. From a roughness curve, a portion having a measurement length L is drawn out in a direction of the central line thereof. The central line of the drawn-out portion is represented by the X axis, and the direction of the vertical magnification is represented by the Y axis. The roughness curve is defined as y−f(x). Ra is represented by the following expression.

$$Ra = \frac{1}{L} {\int }_{O}^{L} \vert f ( x ) \vert dx \qquad [ Expression 1 ]$$

Ra may be measured by use of a contact-type surface roughness meter, a laser microscope or the like. In this specification, the laser microscope VK-250 produced by Keyence Corporation is used.

The roughened upper surface 61a of the base portion 61 may have striped convexed and concaved portions or dot-like convexed and concaved portions (satin-finished surface). For example, the striped convexed and concaved portions extend in the x direction or the y direction.

It is preferred that the base portion 61 has a light transmittance of 90% or higher at a peak wavelength of each of the plurality of light emitting elements 50. This arrangement may further improve the light retrieval efficiency of the light emitting device 1000A.

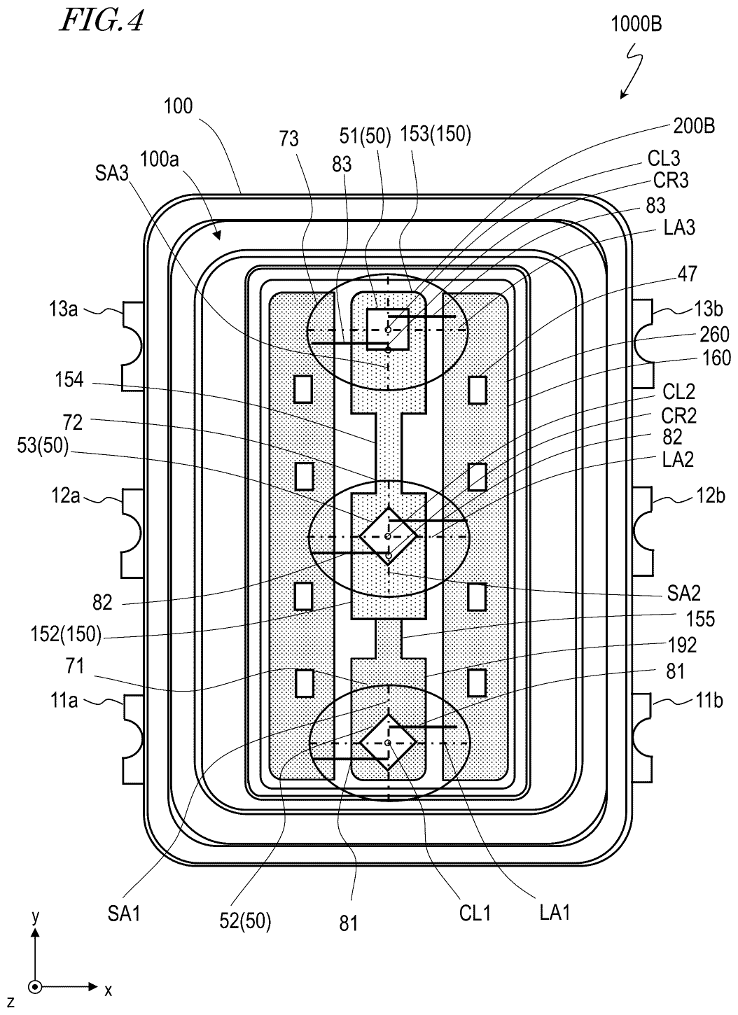

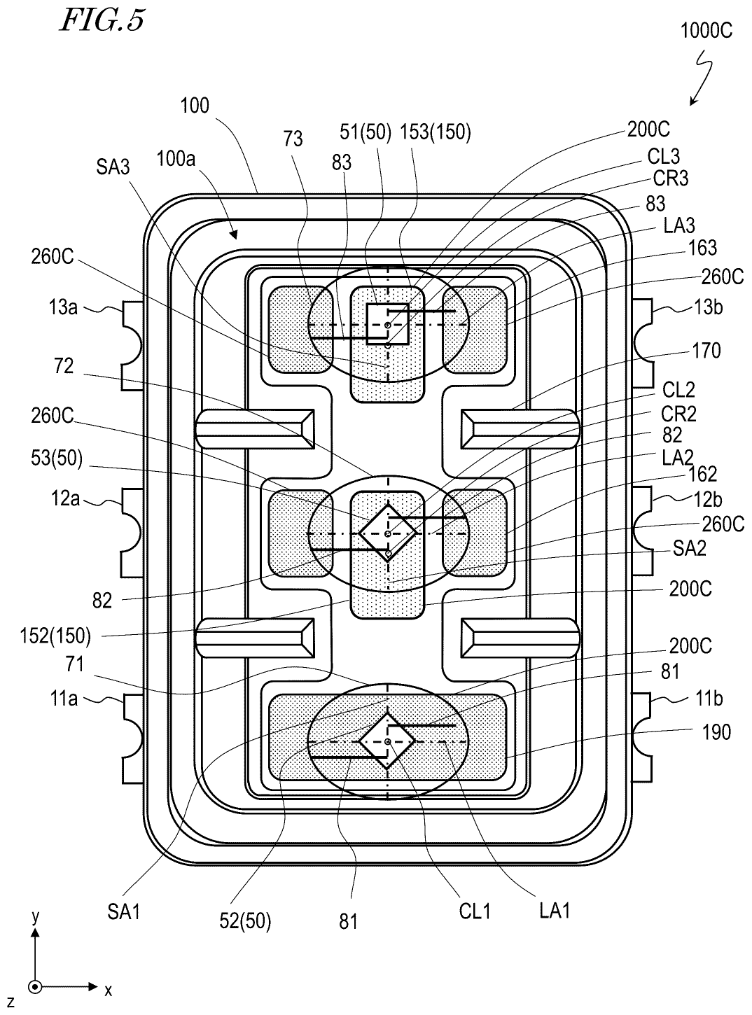

Now, with reference to FIG. 4 through FIG. 7A and FIG. 7B, light emitting devices 1000B through 1000E in other embodiments according to the present disclosure will be described. The light emitting devices 1000B through 1000E each basically include the first light emitting element 51, the lens portion 73 overlapping the first light emitting element 51, and the reflective member 153 disposed in the vicinity of the first light emitting element 51, which are disposed in substantially the same positional relationship as that of the light emitting device 1000A. The light emitting devices 1000B through 1000E also each basically include the third light emitting element 53, the lens portion 72 overlapping the third light emitting element 53, and the reflective member 152 disposed in the vicinity of the third light emitting element 53, which are disposed in substantially the same positional relationship as that of the light emitting device 1000A. Therefore, the light emitting devices 1000B through 1000E may each provide effects common to those of the light emitting device 1000A. The light emitting devices 1000B through 1000E each basically include the second light emitting element 52 and the light absorbing member 190 disposed in the vicinity of the second light emitting element 52, which are substantially the same as those of the light emitting device 1000A. Hereinafter, differences of the light emitting devices 1000B through 1000E from the light emitting device 1000A will be mainly described.

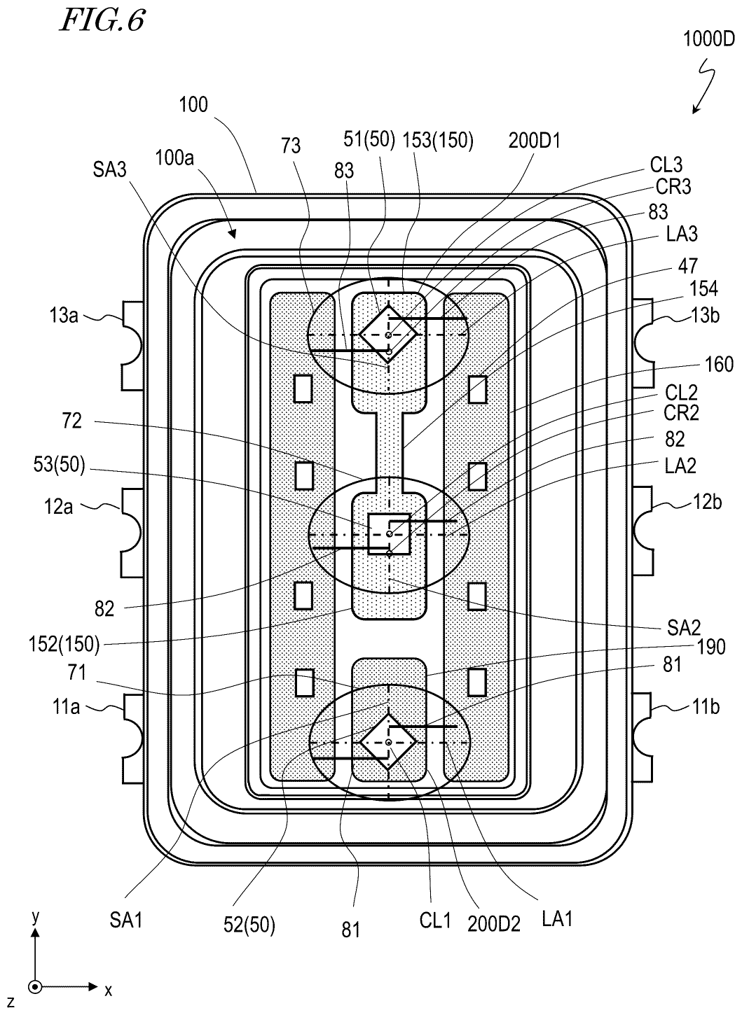

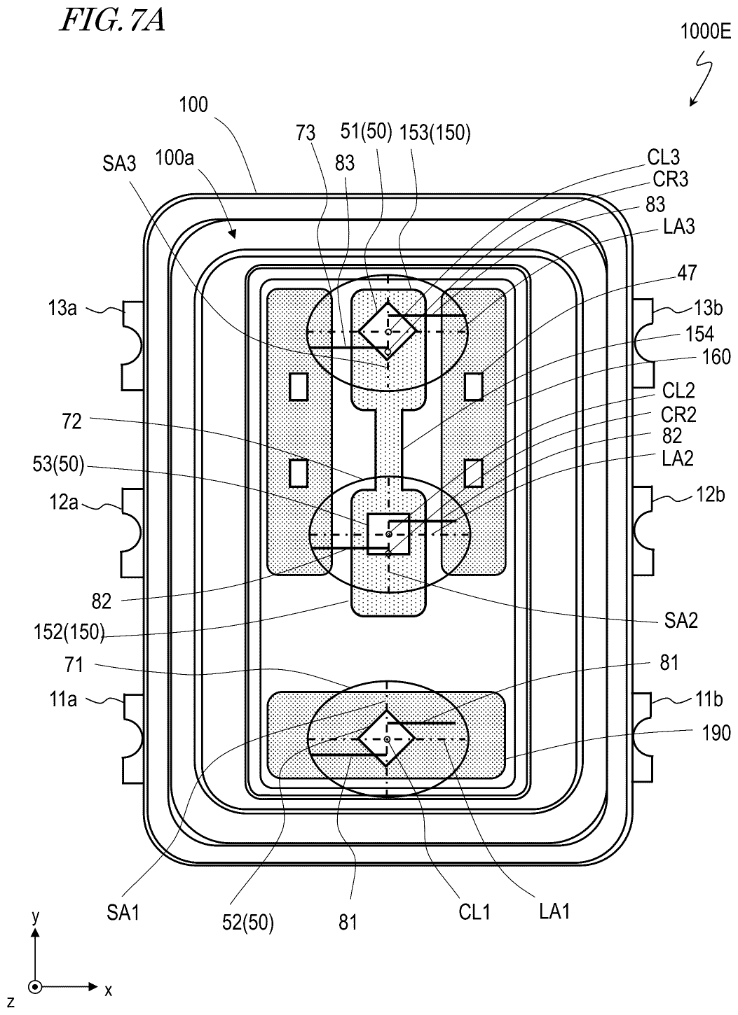

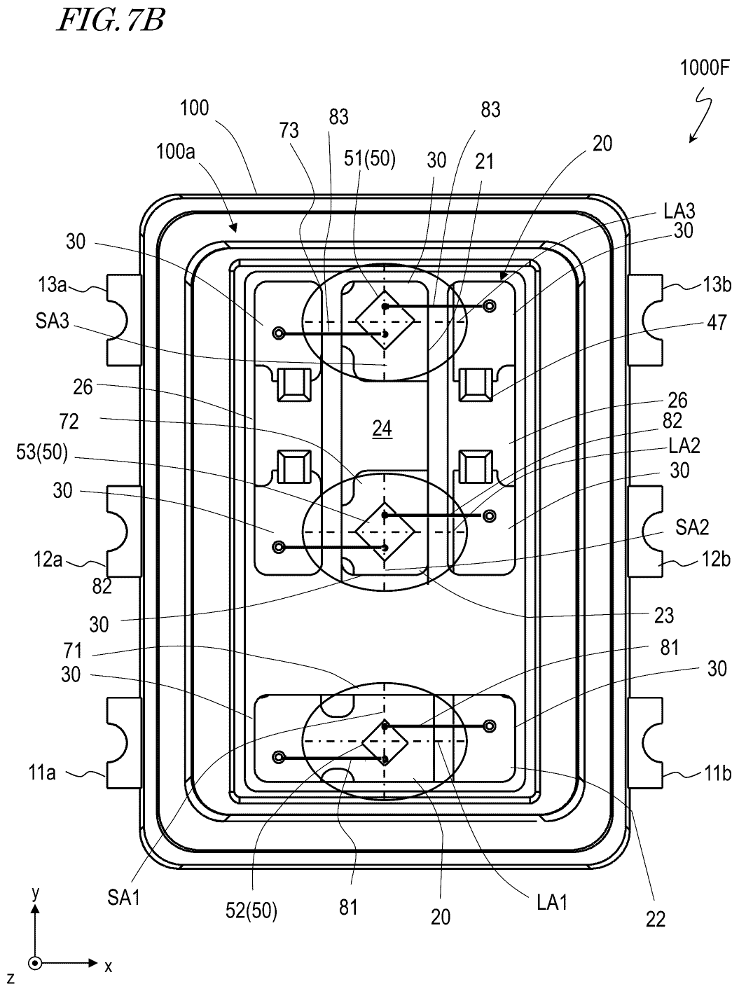

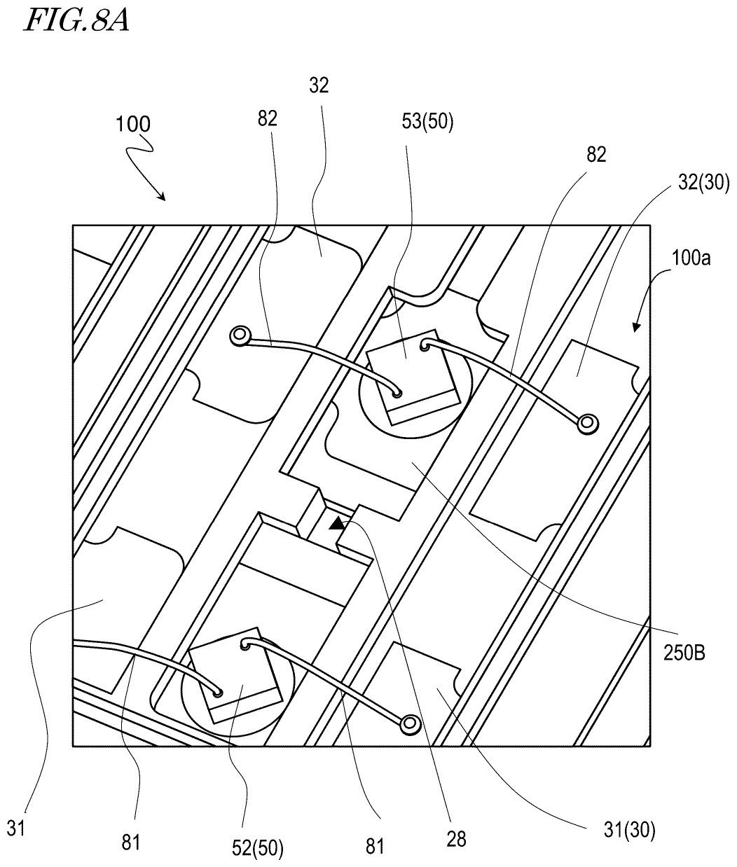

FIG. 4 is a schematic plan view of the light emitting device 1000B in an embodiment according to the present disclosure. FIG. 5 is a schematic plan view of the light emitting device 1000C in an embodiment according to the present disclosure. FIG. 6 is a schematic plan view of the light emitting device 1000D in an embodiment according to the present disclosure. FIG. 7A is a schematic plan view of the light emitting device 1000E in an embodiment according to the present disclosure. FIG. 7B is a schematic plan view of a resin package 100 of the light emitting device 1000F in an embodiment according to the present disclosure.

The light emitting device 1000B shown in FIG. 4 is different from the light emitting device 1000A in that the reflective members 150 of the light emitting device 1000B include coupling portions 154 and 155. The coupling portion 154 couples the reflective member 152 and the reflective member 153 with each other. The coupling portion 154 is integrally disposed with the reflective member 152 and the reflective member 153. The coupling portion 155 couples the reflective member 152 and a light absorbing member 192. The coupling portion 155 may be a portion of the light absorbing member 190, a portion of the reflective member 150, or a portion of the light absorbing member 192 and the reflective member 150. A border along which the reflective member 150 and the light absorbing member 192 contact each other may be visually recognizable with materials thereof not being mixed together, or may be difficult to be visually recognized with the materials thereof being mixed together. In the example shown in FIG. 4, the coupling portion 155 is the light absorbing member 192. In the light emitting device 1000A shown in FIG. 3A, one first region 20 is disposed in correspondence with each of the lens portions 71 through 73. By contrast, in the light emitting device 1000B shown in FIG. 4, one first region 200B is disposed for the lens portions 71 through 73 arranged in the y direction. The reflective member 153, the coupling portion 154, the reflective member 152, the coupling portion 155 and the light absorbing member 192 are disposed in the one first region 200B. The first light emitting element 51, the second light emitting element 52 and the third light emitting element 53 are disposed in the one first region 200B. As seen in a plan view, the first light emitting element 51 is disposed on the side of the +y direction in the first region 200B, so as to be away from the coupling portion 154. The second light emitting element 52 is disposed on the side of the −y direction in the first region 200B, so as to be away from the coupling portion 154. The third light emitting element 53 is disposed closer to the coupling portion 154 than to the coupling portion 155. A portion, of the first region 200B, in which the light emitting elements 50 are disposed, has a length in the x direction that is longer than a length of a portion, of the first region 200B, in which the coupling portions 154 and 155 are disposed. A length of the coupling portion 154 in the x direction is shorter than the length of the reflective member 152 and the reflective member 153 in the x direction. With this arrangement, as compared with the case where the length of the coupling portion 154 is equal to the length of each of the reflective member 152 and the reflective member 153, the light emitting device 1000B may allow the region of the reflective members 150 disposed on the main surface 100B to be smaller as seen in a plan view. Therefore, the contrast ratio of the light emitting device 1000B may be further improved. The length of each of the coupling portions 154 and 155 is shorter than the length of the first region 200B in the x direction. The coupling portions 154 and 155 each have a width shorter than that of the portion, of the first region 200B, in which the light emitting elements 50 are disposed.

The light emitting device 1000B is different from the light emitting device 1000A in that the plurality of exposed regions 30 of the light emitting device 1000B are disposed in one second region 260B. In the second region 260B, the wires 81 through 83 respectively connected with the first light emitting element 51, the second light emitting element 52 and the third light emitting element 53 are disposed. The second region 260B extends in the y direction. With this arrangement, nozzles may be disposed at positions far from the wires. This makes it difficult for the nozzles to contact the wires 81 through 83. As shown in FIG. 4, the first region 200B is disposed between two such second regions 260B. The light absorbing member 160 is disposed in each of the second regions 260B.

The light emitting device 1000B is also different from the light emitting device 1000A in that the light emitting device 1000B includes eight protrusions 47. In the example shown in FIG. 4, four protrusions 47 are disposed on the side of the +y direction with respect to the major axis LA2 of the lens portion 72, and four protrusions 47 are disposed on the side of the −y direction with respect to the major axis LA2 of the lens portion 72. The protrusions 47 do not overlap any of the light emitting elements 50 in the x direction.

The light emitting device 1000C shown in FIG. 5 is different from the light emitting device 1000A in that in the light emitting device 1000C, a pair of second regions 260C are respectively disposed in correspondence with the first region 200C for the first light emitting element 51 and the first region 200C for the third emitting element 53. As seen in a plan view, the pair of second regions 260C are disposed to be out of contact with each other. Light absorbing members 162 and 163 are respectively disposed in the second regions 260C. The resin member 40 is disposed between the second region 260C for the first light emitting element 51 and the second region 260C for the third light emitting element 53 in the y direction. With this arrangement, the light may be absorbed stably. A reason for this is that the resin member 40 has a smaller variation in the light absorptivity than the light absorbing member 162. The light emitting device 1000C is different from the light emitting device 1000A in that recessed portions 170 are disposed between the light absorbing members 162 and the light absorbing members 163 and between the light absorbing members 162 and the light absorbing member 190 in the light emitting device 1000C. The recessed portions 170 are each provided by a portion of the resin package 100 being recessed in the −z direction. In the example shown in FIG. 5, the plurality of recessed portions 170 are disposed. The plurality of recessed portions 170 are, for example, V-shaped, U-shaped, of a trapezoid having a bottom side shorter than a top side, or semicircular. The mold resin portion 60 is disposed in each of the recessed portions 170, so that the adhesiveness between the resin package 100 and the mold resin portion 60 may be improved.

The light emitting device 1000D shown in FIG. 6 is different from the light emitting device 1000B shown in FIG. 4 in that the light emitting device 1000D does not include the coupling portion 155, which is included in the light emitting device 1000B. The light absorbing member 192 and the reflective member 152 are disposed to be out of contact with each other. The light emitting device 1000D includes a first region 200D1, in which the first light emitting element 51 and the third light emitting element 53 are disposed, and a second region 200D2, in which the second light emitting element 52 is disposed. One first region 200D1 is disposed in correspondence with the lens portions 72 and 73 arranged in the y direction. In the second region 200D2, the second light emitting element 52 is disposed on the side of the −y direction in the second region 200D2. In the first region 200D1, the reflective members 150 are disposed. In the second region 200D2, the light absorbing member 190 is disposed. As seen in a plan view, only the resin member 40 is disposed between the reflective member 152 and the light absorbing member 190. In the case where the resin member 40 is formed of a dark color resin, the light may be absorbed stably. A reason for this is that the resin member 40 has a smaller variation in the light absorptivity than the light absorbing member 162.

The light emitting device 1000E shown in FIG. 7A is different from the light emitting device 1000A shown in FIG. 3A in that the light emitting device 1000E includes the coupling portion 154 coupling the reflective member 152 and the reflective member 153 to each other. As seen in a plan view, the resin member 40 is disposed between the reflective member 152 and the light absorbing member 190. In the case where the resin member 40 is formed of a dark color resin, the light may be absorbed stably. A reason for this is that the resin member 40 has a smaller variation in the light absorptivity than the light absorbing member 162.

FIG. 7B shows a schematic plan view of the resin package 100 of the light emitting device 1000F in an embodiment according to the present disclosure. The light emitting device 1000F shown in FIG. 7B is different from the light emitting device 1000A shown in FIG. 3B in that the light emitting device 1000F further includes a connection region 24 connecting the first region 21 corresponding to the lens portion 73 and the first region 23 corresponding to the lens portion 72 to each other. The reflection members 150 are disposed in the first region 21, the first region 23 and the connection region 24. Therefore, in the light emitting device 1000F, the reflective members 150 corresponding to the reflective member 153, the reflective member 152 and the coupling portion 154 coupling the reflective member 153 and the reflective member 152 to each other, which are disposed in the light emitting device 1000E shown in FIG. 7A, are respectively formed in the first region 21, the first region 23 and the connection region 24. In the light emitting device 1000E shown in FIG. 7A, the length in the x direction of the coupling portion 154 is shorter than the length in the x direction of each of the reflective member 153 and the reflective member 152. By contrast, in the light emitting device 1000F shown in FIG. 7B, the length in the x direction of the reflective member 150 formed in the connection region 24 is equal to the length in the x direction of the reflective member 150 formed in each of the first region 21 and the first region 23. In the light emitting device 1000F, a nozzle of a dispenser may be located between the first light emitting element 51 and the third light emitting element 53. Therefore, the reflective members 150 are put to the vicinity of the first light emitting element 51 and the third light emitting element 53 at the same time. This may simplify the production process of the light emitting device 1000F. In the light emitting device 1000F, the reflective members 150 containing a light-reflective substance may be located as being continuous from the vicinity of the first light emitting element 51 to the vicinity of the third light emitting element 53. This arrangement may improve the heat dissipation properties. A reason for this is that the reflective members 150 have a higher heat conductivity than that of the resin member 40. For example, the heat generated by the first light emitting element 51 may be dissipated through a lead on which the first light emitting element 51 is disposed, as well as through the light-reflective substance contained in the reflective members 150 and a lead on which the third light emitting element 53 continuous from the first light emitting element 51 via the reflective members 150 is disposed.

In FIG. 7B, the positional relationship of the first light emitting element 51, the lens portion 73 overlapping the first light emitting element 51, and the reflective member 153 disposed in the vicinity of the first light emitting element 51 is substantially the same as that of the light emitting device 1000A shown in FIG. 3A. With this arrangement, light emitted from the first light emitting element 51 may be used effectively. For example, the first light emitting element 51, which emits blue light, has a luminous intensity lower than that of the light emitting element emitting red light or green light. Therefore, the decrease in the contrast ratio of the first light emitting element 51 emitting blue light is alleviated, and thus the decrease in the contrast ratio of the light emitting device 1000E may be alleviated. The positional relationship of the third light emitting element 53, the lens portion 72 overlapping the third light emitting element 53 and the reflective member 152 disposed in the vicinity of the third light emitting element 53 is different from that of the light emitting device 1000A. As seen in a plan view, a region of the reflective member 152 overlaps the lens portion 72. A portion, of the region, that is present on the side of the −y direction with respect to the major axis LA2 has an area size smaller than an area size of a portion, of the region, that is present on the side of the +y direction with respect to the major axis LA2.

In the light emitting device 1000E shown in FIG. 7A, the first light emitting element 51, which is generally square, and the second light emitting element 52, which is generally square, are each disposed such that one side thereof makes an angle of 45° with respect to the x axis. One side of the third light emitting element 53 is parallel to the x axis. By contrast, in the light emitting device 1000F shown in FIG. 7B, the first light emitting element 51, the second light emitting element 52 and the third light emitting element 53 are each disposed such that one side thereof makes an angle of 45° with respect to the x axis. Alternatively, only the first light emitting element 51 and the third light emitting element 53 may be disposed such that one side thereof makes an angle of 45° with respect to the x axis. The first light emitting element 51 and the third light emitting element 53 are, for example, a blue LED chip and a green LED chip, respectively.

As described above, a light emitting device in an embodiment according to the present disclosure may be modified in any of various manners or combined in any of various manners.

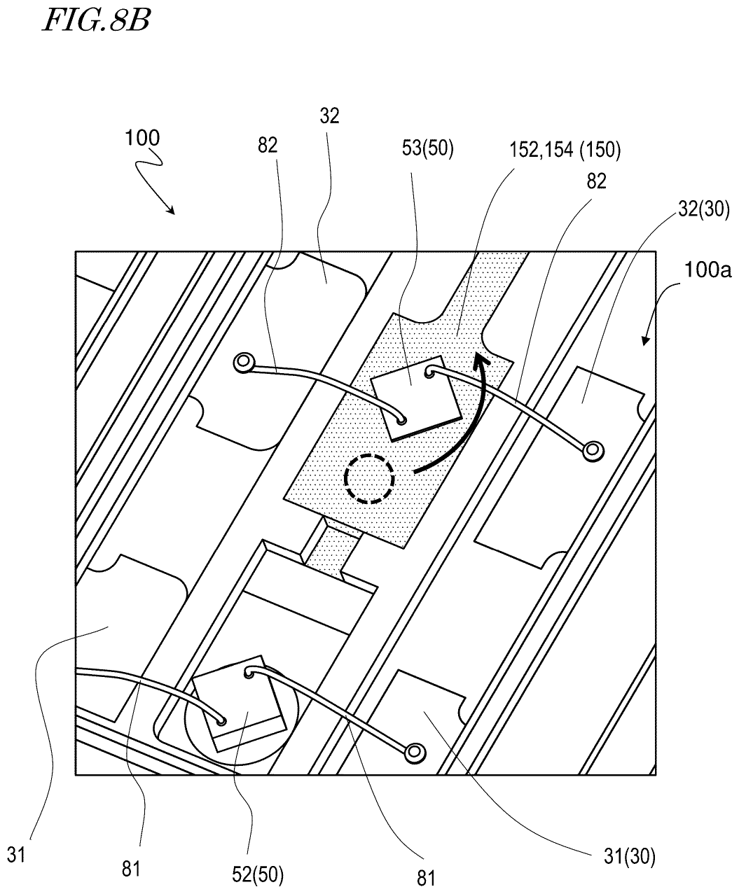

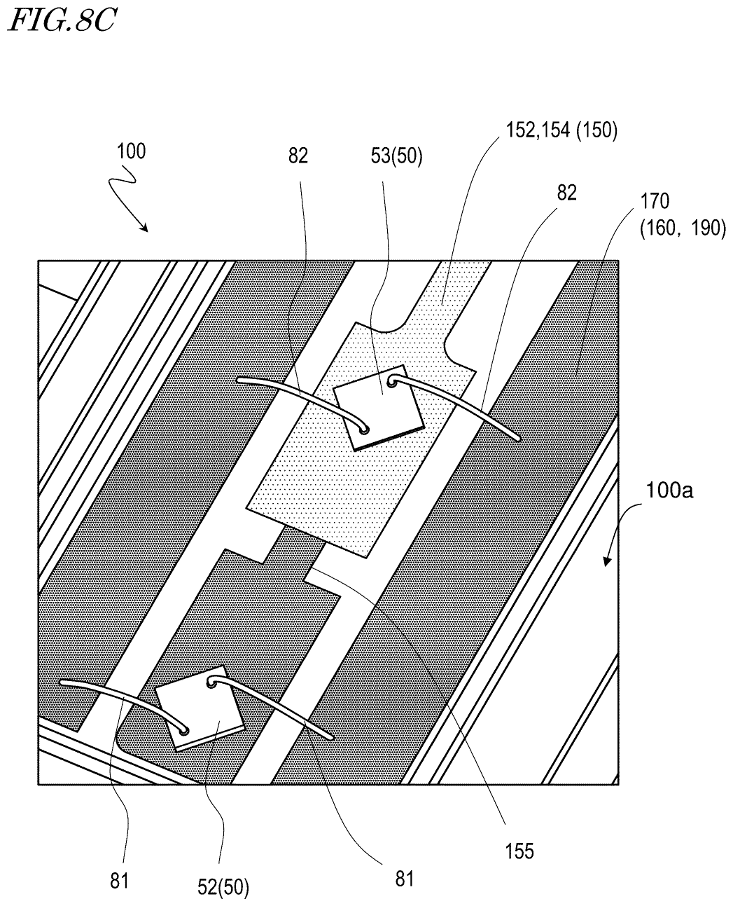

As shown in FIG. 8A, the main surface 100a of the resin package 100 includes the first region 250B. The first region 250B includes a recessed portion 28 between the third light emitting element 53 and the second light emitting element 52. The recessed portion 28 is recessed deeper than a region where the third light emitting element 53 is disposed and a region where the second light emitting element 52 is disposed. The first region 250B has the third light emitting element 53 disposed on an exposed region 32. The third light emitting element 53 is disposed closer to the coupling portion 154 than to the coupling portion 155. The second light emitting element 52 is disposed on an exposed region 31. The second light emitting element 52 is disposed on the side of the −y direction in the first region 250B.

As shown in FIG. 8B, the reflective resin material is provided by a nozzle (not shown) of a dispenser put closer to a position represented by the dashed-line circle in the figure. The reflective resin material is provided so as to go around the third light emitting element 53 as represented by the arrow in the figure. The reflective member 152 is formed in this manner. Note that an extra portion of the reflective resin material may be stored in the recessed portion 28 or may be expanded over the recessed portion 28 and provided on the side of the second light emitting element 52. The third light emitting element 53 is disposed closer to the coupling portion 154 than to the coupling portion 155, so that a region below the third light emitting element 53 (on the side of the −y direction with respect to the third light emitting element 53) may be made larger. Therefore, the reflective resin material may be provided by the nozzle of the dispenser put closer to the main surface 100a.

Now, as shown in FIG. 8C, a light absorbing resin material is provided in the first region 200B. The light absorbing resin material is provided so as to surround the second light emitting element 52. In this manner, the light absorbing member 192 and the coupling portion 155 may be formed. The light absorbing material is provided as overlapping the reflective resin material disposed in the recessed portion 28. The light absorbing material may be expanded over the recessed portion 28 and provided on the side of the third light emitting element 53 on the condition that the light absorbing material does not overlap an upper surface of the light emitting element 53.

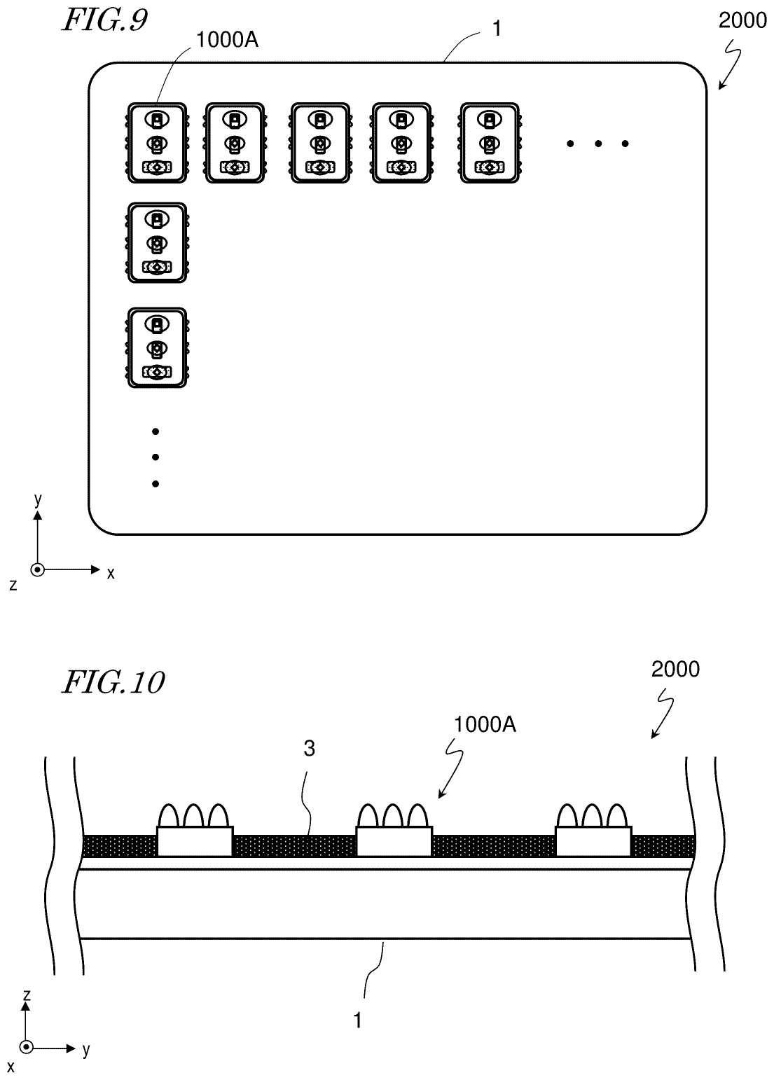

Now, with reference to FIG. 9 and FIG. 10, a display device 2000 according to the present disclosure will be described. The display device 2000 is applicable as, for example, a display device for outdoor display or the like. FIG. 9 is a schematic plan view of the display device 2000 in an embodiment according to the present disclosure. FIG. 10 is a schematic partial cross-sectional view of the display device 2000.

As shown in FIG. 9, the display device 2000 includes a plurality of the light emitting devices 1000A arranged in a matrix including rows and columns. Each of the light emitting devices 1000A acts as a color display pixel. Any other light emitting device according to the present disclosure may be used instead of the light emitting device 1000A. The plurality of light emitting devices 1000A are arranged so as to form rows in the x direction and to form columns in the y direction. As shown in FIG. 9, the light emitting devices 1000A are each disposed so as to have the first light emitting element 51, the third light emitting element 53 and the second light emitting element 52 provided in this order from the side of the +y direction to the side of the −y direction. It is preferred that the first light emitting element 51 emits blue light, the third light emitting element 53 emits green light and the second light emitting element 52 emits red light. In the case where the plurality of light emitting devices 1000A are directly visually recognized, green light looks brighter than blue or red light even though these colors of light are of the same amount, for a reason that green has a higher spectral luminous efficacy than that of blue or red. Therefore, the third light emitting element 53 emitting green light is disposed at the center, so that the color mixing property of the light emitting device 1000A may be improved. The first light emitting element 51 emitting blue light is disposed close to a louver that blocks external light, so that a situation may be alleviated where the external light, which is other than the light emitted by the light emitting elements 50, further deteriorates the resin. The resin used for the light emitting device 1000A may possibly be deteriorated by light having a short wavelength. Such a deterioration in the resin easily occurs at a position close to the first light emitting element 51 emitting blue light having the shortest wavelength. Therefore, external light that is incident on a position close to the first light emitting element 51 emitting blue light is blocked, so that further deterioration of the resin may be alleviated. The above-described effects of the light emitting devices 1000A allow the display device 2000 to provide a display having a high contrast ratio.

As shown in FIG. 10, the display device 2000 includes the plurality of light emitting devices 1000A as well as a substrate 1, such as a printed circuit board on which the plurality of light emitting devices 1000A are arranged two-dimensionally, and a waterproof resin 3. The waterproof resin 3 is disposed so as to cover lateral surfaces of the plurality of light emitting devices 1000A. An uppermost end of a portion where the waterproof resin 3 and the outer lateral surfaces of the mold resin portion 60 are in contact with each other may be (1) the position of the second point Q, (2) any position, on the outer lateral surface of the lateral surface portion 61b of the base portion 61, that is between the second point Q and the third point R, or (3) any position, on the outer lateral surface of the lateral surface portion 61b of the base portion 61, that is between the first point P and the second point Q. The waterproof resin 3 may be formed of, for example, a silicone resin.

In this example, the display device 2000 is described as being usable for outdoor display. There is no specific limitation on the use of the display device 2000.

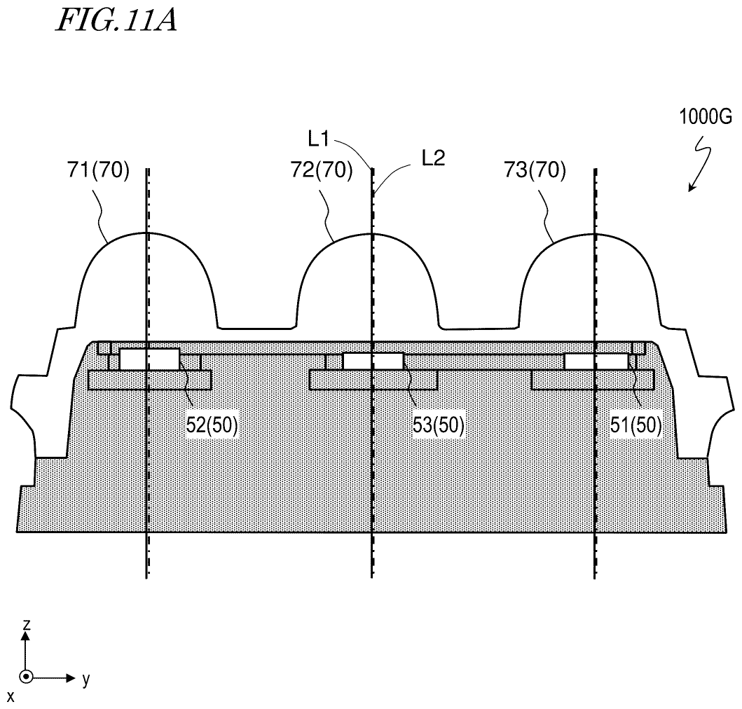

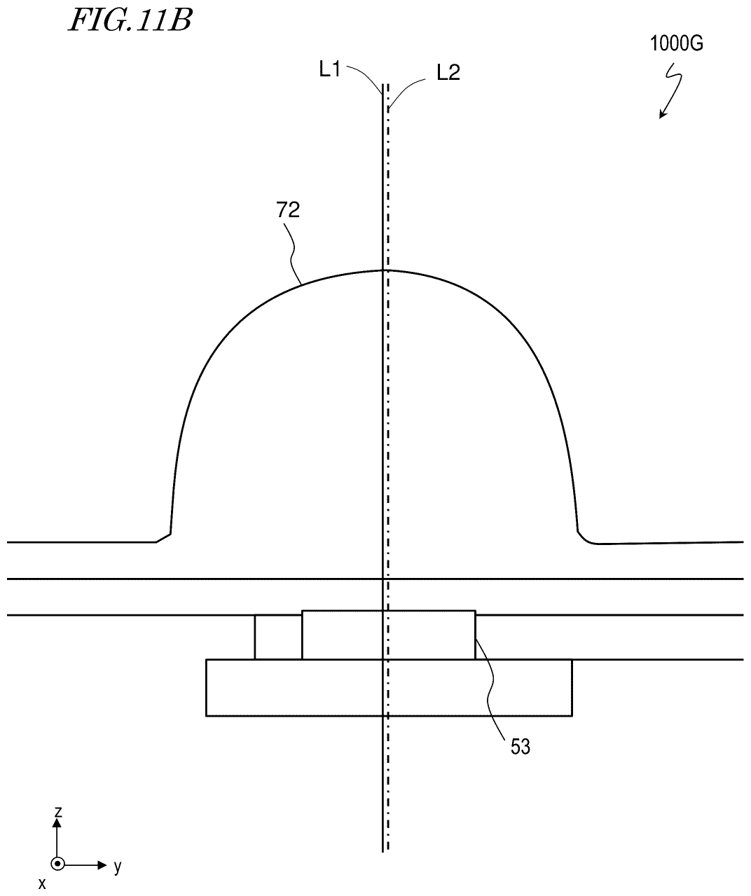

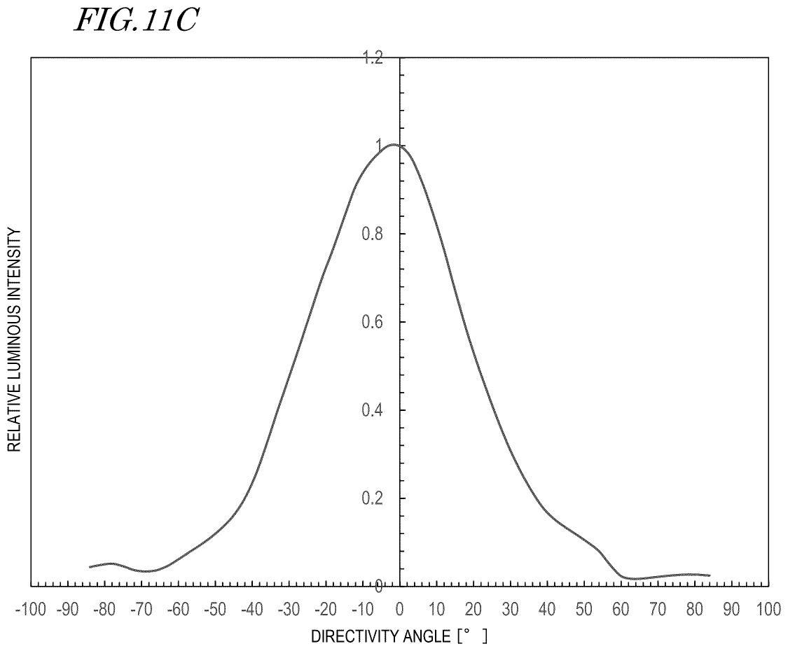

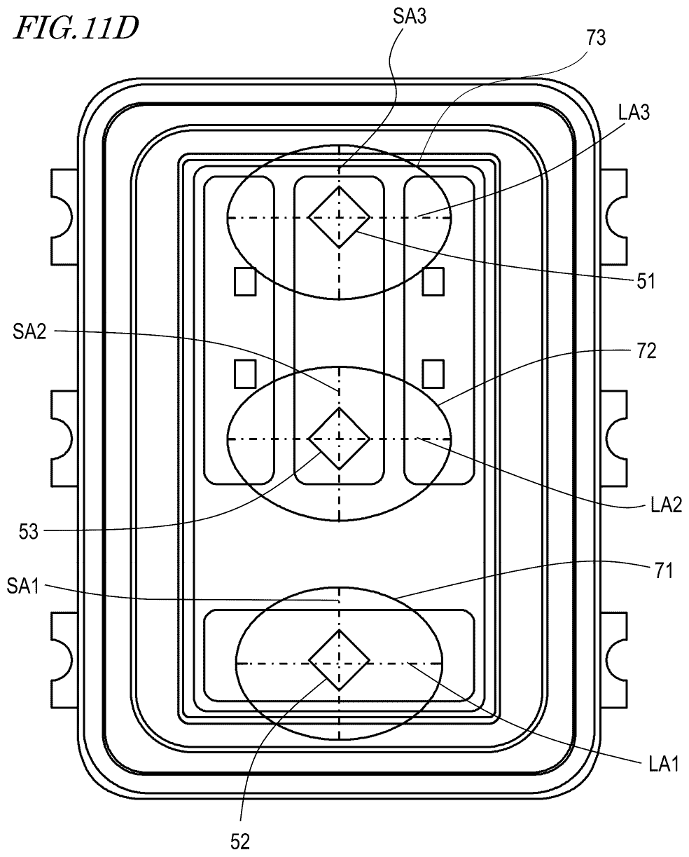

FIG. 11A is a schematic cross-sectional view of a light emitting device 1000G in an embodiment according to the present disclosure. FIG. 11B is an enlarged schematic partial cross-sectional view of the light emitting device 1000G. FIG. 11C is a graph showing the relative luminous intensity vs. directivity angle relationship of the light emitting device 1000G. FIG. 11D is a schematic plan view of the light emitting device 1000G.

The light emitting device 1000G is different from the light emitting device 1000A shown in FIG. 3A in that the apexes of the lens portions 70 and the centers of the light emitting elements 50 are not on the same straight lines in the light emitting device 1000G.

In the case where, for example, the display device 2000 used outdoors is looked up to from below, the luminous intensity distribution is broadened in the −y direction, which is the direction in which the display device 2000 is observed, so that the visual recognizability of the light emitting devices 1000A may be improved. The expression that “the luminous intensity distribution is broadened in the −y direction” indicates that the directivity angle at which the relative luminous intensity is 0.5 is broader on the side of the −y direction and narrower on the side of the +y direction with respect to the central axis of the directivity angle. In the example shown in FIG. 11A and FIG. 11B, the light emitting device 1000G may have (1) an arrangement where straight lines L1 and the centers of the light emitting elements 50 are shifted from each other and the radius of curvature of each of the lens portions 70 is made asymmetrical and (2) an arrangement where the straight lines L1 and the centers of the light emitting elements 50 are shifted from each other and the radius of curvature of each of the lens portions 70 is made symmetrical. Note that the light emitting device 1000G may have (3) an arrangement where the straight lines L1 and the centers of the light emitting elements 50 match each other and the radius of curvature of each of the lens portions 70 is made asymmetrical.

The apex of each lens portion 70 is shifted with respect to the center of the corresponding light emitting element 50, so that the luminous intensity distribution of the light emitting device 1000G may be adjusted. FIG. 11A and FIG. 11B each show the straight line L1 passing the center of each lens portion 70 and being parallel to the z axis, and a straight line L2 passing the center of each light emitting element 50 and being parallel to the z axis. In FIG. 11A and FIG. 11B, the straight lines L1 are represented by solid lines, and the straight lines L2 are represented by one-dot chain lines. FIG. 11A is a cross-sectional view taken along the y axis and the z axis. In the light emitting device 1000G, the straight lines L1 are located further on the side of the −y direction than the straight lines L2. Therefore, the optical axis of each lens portion 70 is shifted in the −y direction and thus does not match the center of the corresponding light emitting element 50. In the case where the light emitting device 1000G is mounted on the display device 2000, the −y direction is a downward direction. Therefore, the light emitting device 1000G may broaden the luminous intensity distribution in the downward direction as compared with the light emitting device 1000A, and thus may further improve the visual recognizability thereof when being looked up to from below. FIG. 11C shows an example of the luminous intensity distribution characteristics of the light emitted through the first lens portion 71 corresponding to the second light emitting element 52. In FIG. 11C, the vertical axis represents the relative luminous intensity, and the horizontal axis represents the directivity angle. The apex of the lens portion 71 is shifted in the −y direction, so that the luminous intensity of the light emitted through the first lens portion 71 corresponding to the second light emitting element 52 is expanded in the −y direction, and the peak of the relative luminous intensity is shifted in the −y direction from the position having a directivity angle of 0°.

An outer perimeter of the second lens portion 72 of the light emitting device 1000G has an asymmetrical shape with respect to the straight line L1. Similarly, an outer perimeter of the third lens portion 73 has an asymmetrical shape with respect to the straight line L1. The outer perimeters of these lens portions 70 each have an asymmetrical shape with respect to the straight line L1, so that the luminous intensity distribution of the light emitting device 1000G may be adjusted. In the second lens portion 72, the radius of curvature of a region on the side of the −y direction with respect to the straight line L1 is smaller than the radius of curvature of a region on the side of the +y direction with respect to the straight line L1. The same is applicable to the third lens portion 73. Note that the first lens portion 71 has a symmetrical shape with respect to the optical axis thereof. In a cross-section along the x axis and the z axis, the outer perimeters of the first lens portion 71 through the third lens portion 73 may be symmetrical or asymmetrical with respect to the straight lines L1.

The light emitting device 1000G may use any of (1) through (3) independently or combine any of (1) through (3) to adjust the luminous intensity distribution. In the light emitting devices 1000A through 1000F, the lens portions 70 may be modified as described in any one of (1) through (3) or may combine any of (1) through (3).

As shown in FIG. 11D, a portion, of an outer circumference of the lens portion 73, that is on the side of the −y direction with respect to the major axis LA3 is larger than a portion, of the outer circumference of the lens portion 73, that is on the side of the +y direction with respect to the major axis LA3. The lens portion 73 has an asymmetrical shape with respect to the major axis LA3. The lens portion 73 has a symmetrical shape with respect to the minor axis SA3. A portion, of an outer circumference of the lens portion 72, that is on the side of the −y direction with respect to the major axis LA2 is larger than a portion, of the outer circumference of the lens portion 72, that is on the side of the +y direction with respect to the major axis LA2. The lens portion 72 has an asymmetrical shape with respect to the major axis LA2. The lens portion 72 has a symmetrical shape with respect to the minor axis SA2. A portion, of an outer circumference of the lens portion 71, that is on the side of the +y direction with respect to a major axis LA1 is of an equal size to a portion, of the outer circumference of the lens portion 71, that is on the side of the −y direction with respect to the major axis LA1. The lens portion 71 has a symmetrical shape with respect to the major axis LA1 and a minor axis SA1. The outer circumference of each lens portion 70 is not limited to having the above-described shape. For example, the outer circumferences of all the lens portions 71 through 73 may have asymmetrical shapes with respect to the major axes LA1 through LA3 respectively and have symmetrical shapes with respect to the minor axes SA1 through SA3 respectively.

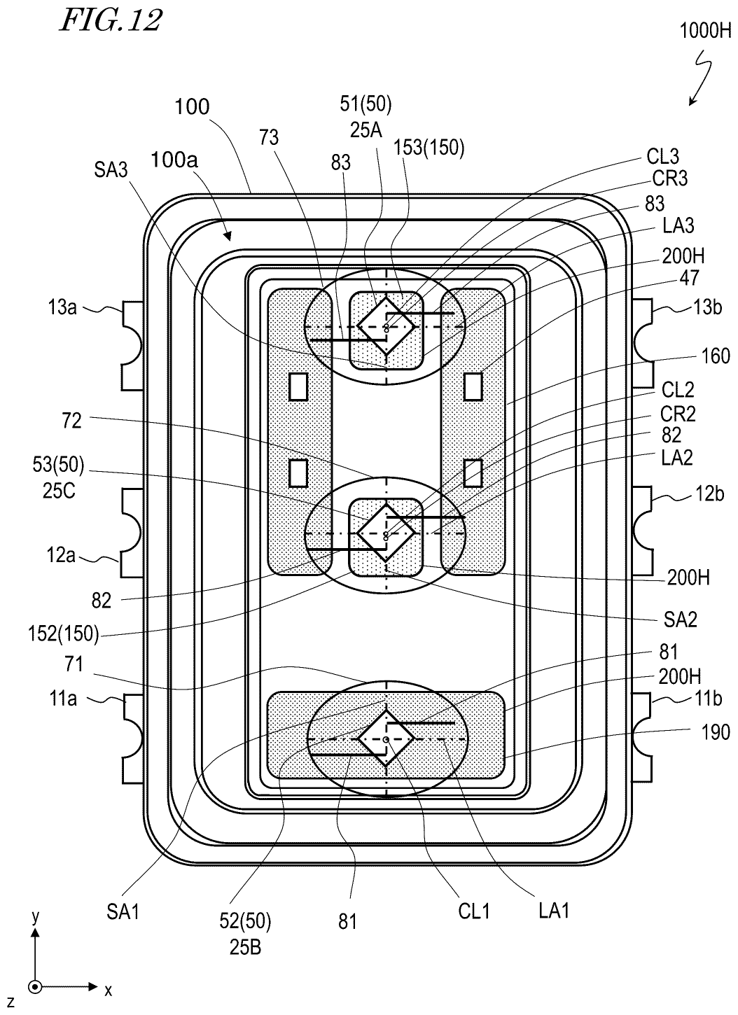

FIG. 12 is a schematic plan view of a light emitting device 1000H in an embodiment according to the present disclosure. The light emitting device 1000H is different from the light emitting device 1000A shown in FIG. 3A in that the reflective members 150 of the light emitting device 1000H entirely overlap the lens portions as seen in a plan view. This arrangement may decrease area sizes of the regions where the reflective members 150 are disposed. The area sizes of the regions where the reflective members 150 are disposed are decreased, so that the decrease in the contrast ratio of the light emitting device 1000H may be alleviated.

The light emitting device 1000H includes a plurality of first regions 200H, in which the first light emitting element 51 through the third light emitting element 53 are disposed. As seen in a plan view, a portion, of the reflective member 153, that is present on the side of the −y direction with respect to the major axis LA3 has an area size smaller than an area size of a portion, of the reflective member 153, that is present on the side of the +y direction with respect to the major axis LA3. The length of the reflective member 153 in the y direction may be longer than the length of the minor axis SA3 of the lens portion 73. The length of the reflective member 153 in the x direction may be equal to, or different from, the length of the reflective member 153 in the y direction. The reflective member 152 has substantially the same configuration as that of the reflective member 153.

### Embodiment 2

Light emitting devices 1000J through 1000M according to embodiment 2 will be described. The light emitting devices 1000J through 1000M according to embodiment 2 each include a base and at least one first light emitting element disposed on the base and emitting light from an upper surface and lateral surfaces thereof, a reflective member disposed in the vicinity of the at least one first light emitting element, and a lens overlapping the at least one first light emitting element as seen in a plan view. The center of the reflective member and the center of the lens match each other. The light emitting devices 1000J through 1000M according to embodiment 2 are each the same as the light emitting elements in embodiment 1 in including the reflective member 150 covering lateral surfaces of the light emitting element 50 as seen in a plan view. The lateral surfaces of the light emitting element 50 are covered with the reflective material as in embodiment 1. Therefore, the light emitted from the lateral surfaces of the light emitting element 50 is reflected by the reflective member 150 and thus is not easily emitted outside. For example, the reflective member 150 may reflect 90% or more of the light emitted from the lateral surfaces of the light emitting element 50. That is, the reflective member is disposed, so that the light from the light emitting element 50 may be emitted mainly from the upper surface of the light emitting element 50. With this arrangement, the light may be retrieved at a high efficiency. It is merely needed that the light emitted mainly from the upper surface of the light emitting element is incident on the lens portion 70. Therefore, the lens portion 70 may have a small external shape as seen in a plan view.

Embodiment 2 is different from embodiment 1 in that the center of the lens portion 70 and the center of the reflective member 150 match each other at least in the y direction as seen in a plan view in embodiment 2.

As seen in a plan view, a portion, of the reflective member 150, that is present on the side of the +y direction with respect to the center of the lens has an area size equal to an area size of a portion, of the reflective member 150, that is present on the side of the −y direction with respect to the center of the lens. In the case where the lens portion 70 is elliptical as seen in a plan view, a portion, of the reflective member 150, that is present on the side of the +y direction with respect to the major axis of the lens portion 70 has an area size equal to an area size of a portion, of the reflective member 150, that is present on the side of the −y direction with respect to the major axis of the lens portion 70. In the case where the lens portion 70 is circular as seen in a plan view, a portion, of the reflective member 150, that is present on the side of the +y direction with respect to a straight line passing the center of the lens portion 70 and being parallel to the x direction has an area size equal to an area size of a portion, of the reflective member 150, that is present on the side of the −y direction with respect to the straight line. In the case where the lens portion 70 is elliptical as seen in a plan view, a portion, of the reflective member 150, that is present on the side of the +x direction with respect to the minor axis of the lens portion 70 has an area size equal to an area size of a portion, of the reflective member 150, that is present on the side of the −x direction with respect to the minor axis of the lens portion 70. In the case where the lens portion 70 is circular as seen in a plan view, a portion, of the reflective member 150, that is present on the side of the +x direction with respect to a straight line passing the center of the lens portion 70 and being parallel to the y direction has an area size equal to an area size of a portion, of the reflective member 150, that is present on the side of the −x direction with respect to the straight line.

The reflective member 150 may be disposed in the vicinity of only the first light emitting element 51 or in the vicinity of each of the first light emitting element 51 and the third light emitting element 53. In the vicinity of the second light emitting element 52, the light absorbing member 190 may be disposed.

Hereinafter, differences from embodiment 1 will be mainly described. Descriptions of like components as those in embodiment 1 will be omitted when necessary.

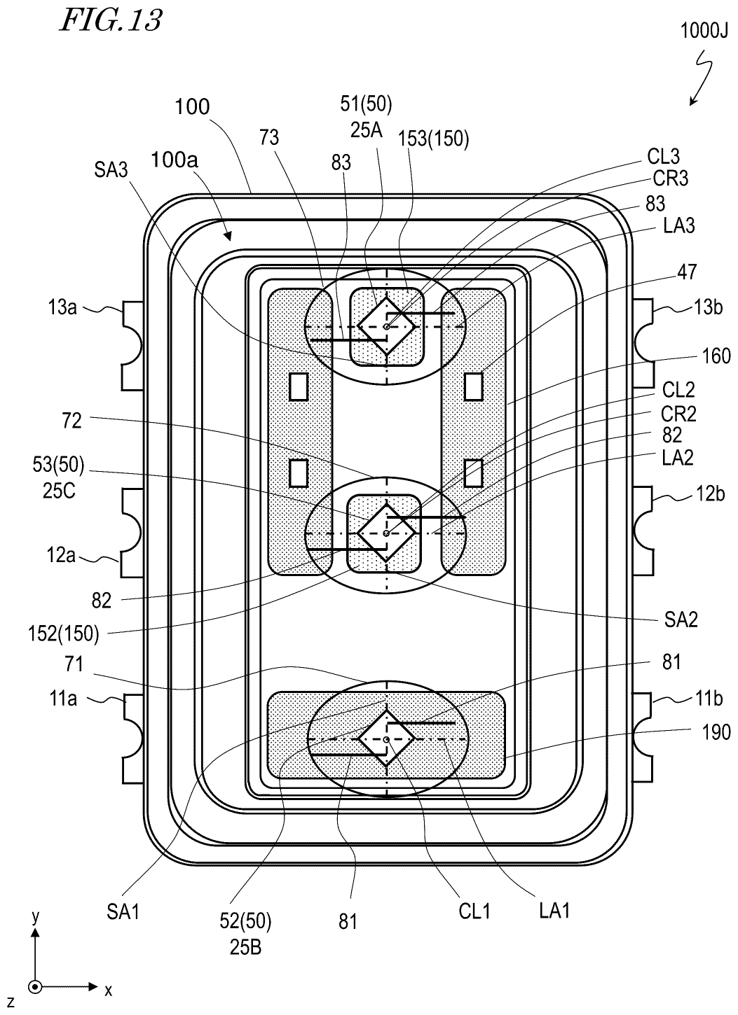

FIG. 13 is a schematic plan view of the light emitting device 1000J in an embodiment according to the present disclosure.

The light emitting device 1000J includes a plurality of first regions 200J, in which the first light emitting element 51 through the third light emitting element 53 are disposed. In the light emitting device 1000J, the center CR3 of the reflective member 153 and the center CL3 of the lens portion 73 match each other. The length of the reflective member 153 in the x direction (first direction) is shorter than the length of the major axis LA3 of the lens portion 73, and the length of the reflective member 153 in the y direction (second direction) is shorter than the length of the minor axis SA3 of the lens portion 73. As seen in a plan view, the length of the reflective member 153 in the x direction and the length of the reflective member 153 in the y direction of the light emitting device 1000J are shorter than those of the light emitting device 1000A. With this arrangement, in the light emitting device 1000J, the resin member 40 included as a dark color resin disposed in the vicinity of the reflective member 153 has an area size larger than that of the light emitting device 1000A. Therefore, the decrease in the contrast ratio of the light emitting device 1000J may be alleviated.

The light emitting element 51, which is generally square, is disposed such that one side thereof makes an angle of 45° with respect to the x axis. The above description is made by way of the light emitting element 51, the lens portion 73 and the reflective member 153. The same is applicable to the third light emitting element 53, the lens portion 72 overlapping the third light emitting element 53 and the reflective member 152 disposed in the vicinity of the third light emitting element 53.

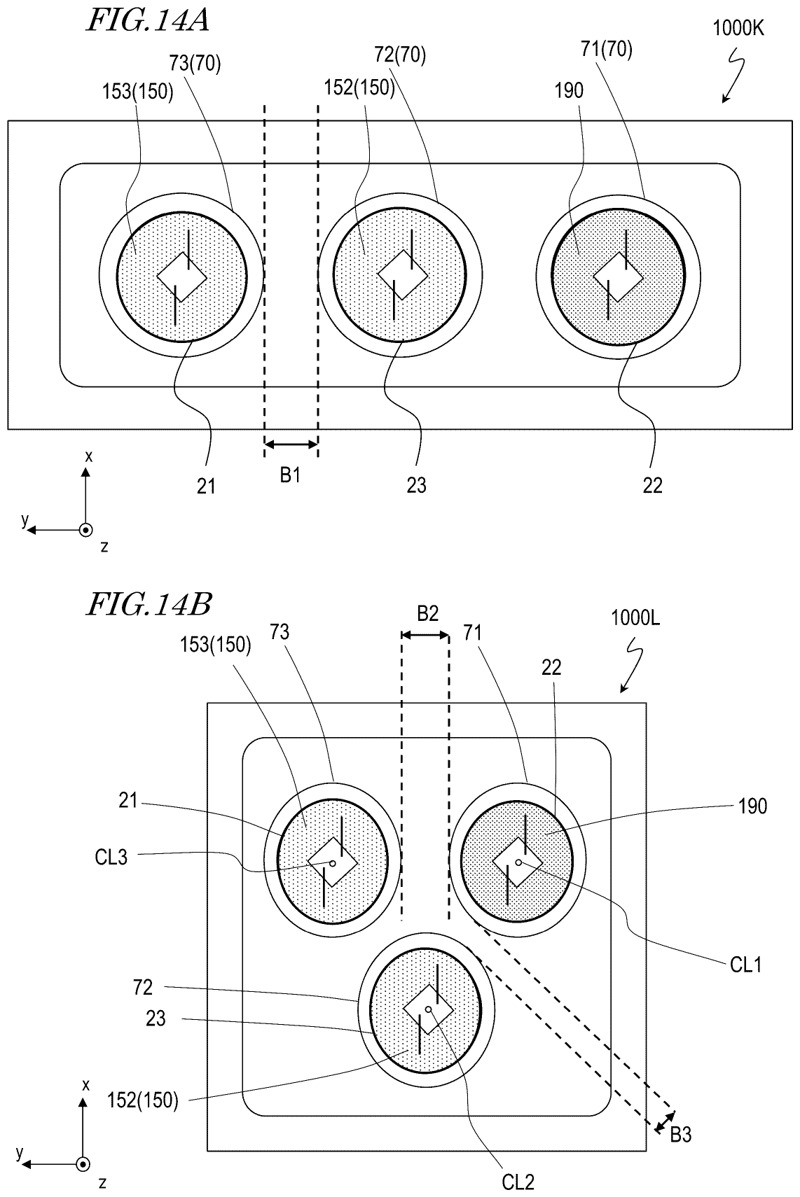

FIG. 14A is a schematic plan view of the light emitting device 1000K in an embodiment according to the present disclosure. In the light emitting device 1000K, the lens portions 70 each have a circular shape as seen in a plan view. In the light emitting device 1000K, the wires 81, 82 and 83 connected with the first light emitting element 51 through the third light emitting element 53 are connected in the first regions 21, 22 and 23. As seen in a plan view. the first regions 21, 22 and 23 have the same shape as, or similar shapes to, each other. The first regions 21, 22 and 23 are each, for example, circular as seen in a plan view. The light emitting device 1000K makes the outer shape of each lens portion 70 small, so that a length B1 between the lens portions 70 may be decreased. The length B1 between the lens portions 70 is the shortest length between the lens portions 70 in a direction in which the centers of the light emitting elements 50 are connected with each other.

FIG. 14B is a schematic plan view of the light emitting device 1000L in an embodiment according to the present disclosure. The light emitting device 1000L is different from the light emitting device 1000K in that in the light emitting device 1000L, the center CL2 of the lens portion 72 located at the center in the y direction among the lens portions 71 through 73 is not located on a line connecting the center CL1 of the lens portion 71 and the center CL3 of the lens portion 73 to each other. The lens portions 71 through 73 are located such that a line segment connecting the centers CL1 through CL3 of the lens portions 71 through 73 form a triangle. The light emitting device 1000L makes the outer shape of each lens portion 70 small, so that lengths B2 and B3 between the lens portions 70 may be decreased. In FIG. 14B, the length B3 is shorter than the length B2. Note that the length B2 may be as long as, or shorter than, the length B3. The lens portions 70 of the light emitting device 1000L are each circular or elliptical as seen in a plan view. The lens portions 70 are elliptical as seen in a plan view, so that the lengths B2 and B3 between the lens portions 70 may be still shorter.

### Embodiment 3

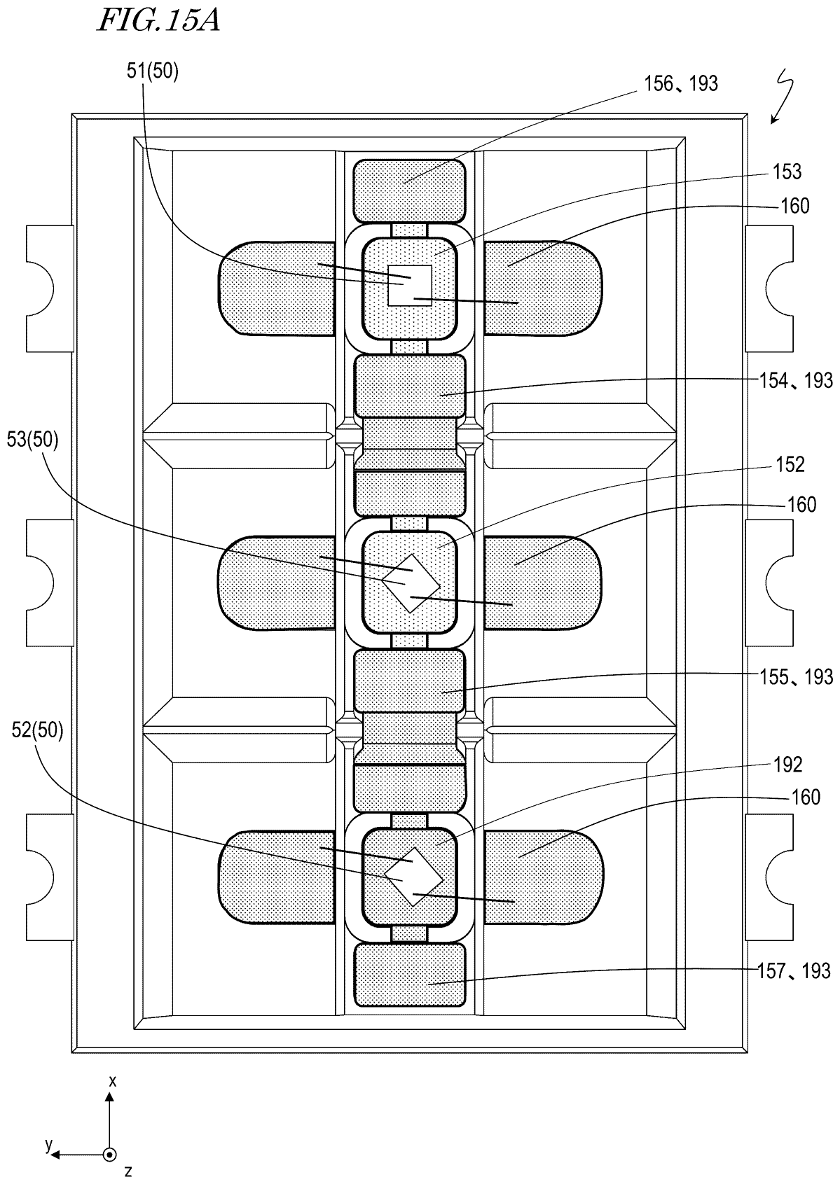

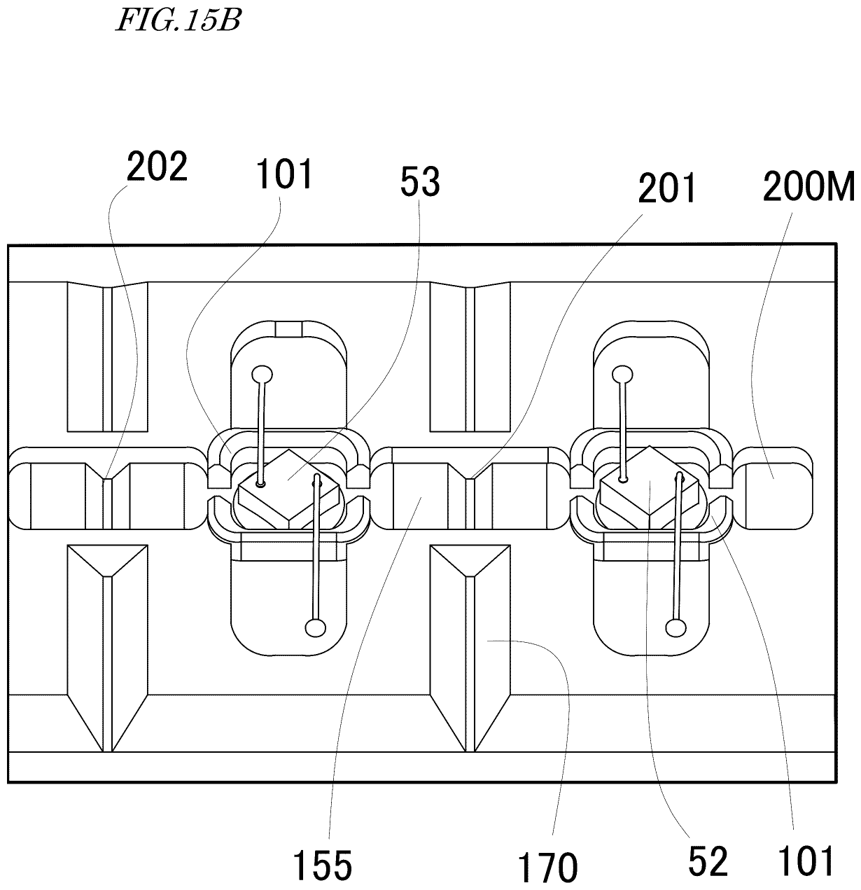

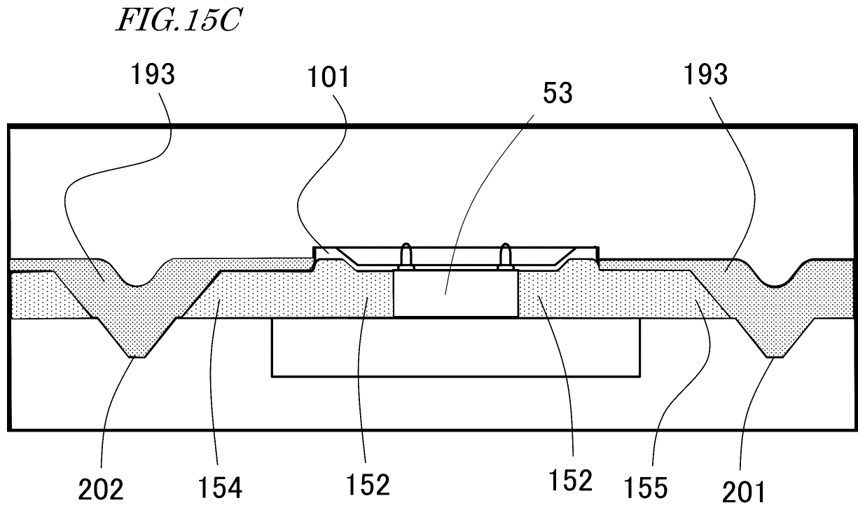

FIG. 15A is a schematic plan view of the light emitting device 1000M in an embodiment according to the present disclosure. FIG. 15B is an enlarged schematic partial perspective view of the light emitting device 1000M. FIG. 15C is an enlarged schematic partial cross-sectional view of the light emitting device 1000M. As shown in FIG. 15A, the light emitting device 1000M includes a light absorbing member disposed between the reflective members in the y direction. That is, the light emitting device 1000M includes a base, at least two first light emitting elements disposed on the base and each emitting light from an upper surface and lateral surfaces thereof, reflective members respectively disposed in the vicinity of the at least two first light emitting elements, the light absorbing member disposed between the at least two first light emitting elements, and lenses overlapping the at least one first light emitting element as seen in a plan view. As seen in a plan view, in the light emitting device 1000M, an area size of a portion, of each reflective member, that is present on the side of the +y direction with respect to a straight line passing the center of the corresponding lens and being parallel to the x direction, and an area size of a portion, of the reflective member, that is present on the side of the −y direction with respect to the straight line, may be equal to, or different from, each other. The light emitting device 1000M is different from the light emitting device 1000J in that in the light emitting device 1000M, one first region 200M is disposed in correspondence with the light emitting elements 51 through 53 arranged in the y direction.

As shown in FIG. 15B, the first region 200M includes a recessed portion 201 between the first light emitting element 51 and the third light emitting element 53. The recessed portion 201 is recessed deeper in the −y direction than a plane on which the first light emitting element 51 and the third light emitting element 53 are disposed. The first region 200M includes a recessed portion 202 between the third light emitting element 53 and the second light emitting element 52. The recessed portion is recessed deeper in the −y direction than the plane on which the third light emitting element 53 and the second light emitting element 52 are disposed.

As shown in FIG. 15C, the reflective member 152 disposed in the vicinity of the third light emitting element 53 is disposed as being continuous from the coupling portion 154. The reflective member 152 is disposed also as being continuous from the coupling portion 155. The light absorbing member 193 is disposed in the recessed portions 201 and 202. The light absorbing member 193 are also disposed as overlapping the coupling portions 154 and 155. Therefore, an area size of a region where the reflective member 150 is disposed may be decreased as seen in a plan view. Therefore, the contrast ratio between when the light emitting device 1000M is lit up and when the light emitting device 1000M is lit out may be improved.

In the light emitting device 1000M, the resin package 100 includes the recessed portions 170. The recessed portions 170 are each provided by a portion of the resin package 100 being recessed in the −z direction. In the example shown in FIG. 15A, four such recessed portions 170 are disposed.

The resin package 100 includes walls 101. The walls 101 are each provided by a portion of the resin package 100 being protruded in the +z direction. As shown in FIG. 15B, the walls 101 are disposed to be out of contact with the light emitting elements 50. The walls 101 each have, for example, a rectangular shape with a portion thereof being cut off. For example, in each of the walls 101 in FIG. 15B, two sides facing each other across the light emitting element 50 each have a portion thereof cut off. The coupling portions 154 and 155 are coupled with the reflective member 153 via the cut-off portions of the rectangular shape.

This specification discloses a light emitting device and a display device described in the following items.

### [Item 1]

A light emitting device, comprising:
a base;
at least one first light emitting element disposed on the base and emitting light from an upper surface and lateral surfaces thereof;
a reflective member disposed in a vicinity of the at least one first light emitting element; and
a lens overlapping the at least one first light emitting element as seen in a plan view,
wherein:
as seen in the plan view, the lens has an elliptical shape having a major axis extending in an x direction and a minor axis extending a y direction perpendicular to the x direction, and
as seen in the plan view, the reflective member disposed in the vicinity of the at least one first light emitting element is disposed such that regarding a region thereof overlapping the lens, a portion, of the region, that is present on a side of a −y direction with respect to the major axis has an area size larger than an area size of a portion, of the region, that is present on a side of a +y direction with respect to the major axis.

### [Item 2]

The light emitting device of item 1, wherein as seen in the plan view, regarding the region, of the reflective member disposed in the vicinity of the at least one first light emitting element, that overlaps the lens, a total length of the region on the major axis is shorter than a total length of the region on the minor axis.

### [Item 3]

The light emitting device of item 1 or 2, wherein:
the at least one first light emitting element includes two first light emitting elements, and
the two first light emitting elements are arranged in the y direction.

### [Item 4]

The light emitting device of any one of items 1 through 3, further comprising a second light emitting element emitting light only from an upper surface thereof,
wherein the second light emitting element and the at least one first light emitting element are arranged in the y direction.

### [Item 5]

The light emitting device of item 4, further comprising a light absorbing member disposed in a vicinity of the second light emitting element.

### [Item 6]

A display device, comprising a plurality of light emitting devices arranged in a matrix including rows and columns,
wherein:
the plurality of light emitting devices are each the light emitting device of any one of items 1 through 5, and
the plurality of light emitting devices are arranged so as to form the rows in an x direction and to form the columns in a y direction.

### [Item 7]

A light emitting device, comprising:
a base;
at least one first light emitting element disposed on the base and emitting light from an upper surface and lateral surfaces thereof;
a first reflective member disposed in a vicinity of the at least one first light emitting element; and
a first lens overlapping the at least one first light emitting element as seen in the plan view,
wherein:
as seen in the plan view, the first lens has an elliptical shape having a major axis extending in a first direction and a minor axis extending in a second direction perpendicular to the first direction, and
the first reflective member has a length in the first direction that is shorter than a length of the major axis of the elliptical shape of the first lens,
a center of the at least one first light emitting element matches a center of the first lens, and
a center of the first reflective member is shifted in the second direction from the center of the first lens, and the center of the first reflective member overlaps the first lens.

### [Item 8]

The light emitting device of item 7, wherein a length of the first reflective member in the second direction is longer than a length of the minor axis of the elliptical shape of the first lens.

### [Item 9]

The light emitting device of item 7 or 8, wherein the length of the first reflective member in the first direction is longer than the length thereof in the second direction.

### [Item 10]

The light emitting device of any one of items 7 through 9, wherein:
the at least one first light emitting element includes two first light emitting elements, and
the two first light emitting elements are arranged in the second direction.

### [Item 11]

A display device, comprising a plurality of light emitting devices arranged in a matrix including rows and columns,
wherein:
the plurality of light emitting devices are each the light emitting device of any one of items 7 through 10, and
the plurality of light emitting devices are arranged so as to form the rows in the first direction and to form the columns in the second direction.

### INDUSTRIAL APPLICABILITY

A light emitting device according to an embodiment of the present disclosure may effectively use light emitted from light emitting elements. A display device including light emitting devices according to the present disclosure may provide a display having a high contrast ratio.

### REFERENCE SIGNS LIST

1000A, 1000B, 1000C, 1000D, 1000E: light emitting device; 3: waterproof resin; 11a through 13a, 11b through 13b: lead; 30, 32: exposed region of the lead; 40: resin member; 47: protrusion; 50: light emitting element; 51: first light emitting element; 52: second light emitting element; 53: third light emitting element; 60: mold resin portion; 61: base portion; 61a: upper surface of the base portion; 61b: lateral surface portion of the base portion; 62: base stepped surface; 70: lens portion; 71: first lens portion; 72: second lens portion; 73: third lens portion; 100: resin package (base); 100a: main surface of the resin package; 100b: rear surface of the resin package; 100c: outer side portion of the resin package; 152, 153: reflective member in the vicinity of the light emitting element; 154: coupling portion (reflective member); 160, 190: light absorbing member (resin member); 1000u: interface; 2000: display device

What is claimed is:

1. A light emitting device, comprising:
a base;
at least one first light emitting element disposed on the base and emitting light from an upper surface and lateral surfaces thereof;
a reflective member disposed in a vicinity of the at least one first light emitting element; and
a lens overlapping, as seen in a plan view, the at least one first light emitting element and the reflective member disposed in the vicinity of the at least one first light emitting element,
wherein:
as seen in the plan view, the lens has an elliptical shape having a major axis extending in an x direction and a minor axis extending in a y direction perpendicular to the x direction, and
as seen in a plan view, regarding a region of the reflective member overlapping the lens, a portion, of the region, that is present on a side of a −y direction with respect to a center of the major axis has an area size larger than an area size of a portion, of the region, that is present on a side of a ty direction with respect to the center of the major axis.

2. The light emitting device of claim 1, wherein as seen in the plan view, regarding the region, of the reflective member disposed in the vicinity of the at least one first light emitting element, that overlaps the lens, a total length of the region on the major axis is shorter than a total length of the region on the minor axis.

3. The light emitting device of claim 1, wherein:
the at least one first light emitting element includes two first light emitting elements, and
the two first light emitting elements are arranged in the y direction.

4. The light emitting device of claim 1, further comprising a second light emitting element emitting light only from an upper surface thereof,
wherein the second light emitting element and the at least one first light emitting element are arranged in the y direction.

5. The light emitting device of claim 4, further comprising a light absorbing member disposed in a vicinity of the second light emitting element.

6. The light emitting device of claim 5, wherein the light absorbing member overlaps a portion of the reflective member disposed in the vicinity of the at least one first light emitting element.

7. A display device, comprising a plurality of light emitting devices arranged in a matrix including rows and columns,
wherein:
the plurality of light emitting devices are each the light emitting device of claim lor 2, and
the plurality of light emitting devices are arranged so as to form the rows in an x direction and to form the columns in a y direction.
